(19) United States
(12) Patent Application Publication
(10) Pub. No.: US 2026/0089978 A1
(43) Pub. Date: Mar. 26, 2026

(54) STACKS OF INTEGRATED CIRCUIT STRUCTURES WITH MEMORY AND BACK-SIDE POWER DELIVERY

(71) Applicant: Intel Corporation, Santa Clara, CA (US)

(72) Inventor: Abhishek A. Sharma, Portland, OR (US)

(73) Assignee: Intel Corporation, Santa Clara, CA (US)

(21) Appl. No.: 18/892,662

(22) Filed: Sep. 23, 2024

(51) Int. Cl. H10B 80/00; H01L 25/00; H01L 25/065

(52) U.S. Cl. CPC H10B 80/00; H10W 90/00

(57) ABSTRACT

IC devices with stacks of IC structures with memory and back-end power delivery are disclosed, where different IC structures of a stack are bonded together. An example IC device includes a first and a second IC structures. The first IC structure includes a layer of memory cells, a power delivery structure at the back side of the layer of memory cells, and a layer of signal interconnects at a front side of the layer of memory cells. The second IC structure is attached to the layer of signal interconnects of the first IC structure and includes a layer of memory cells and a power delivery structure at a back side of the layer of memory cells of the second IC structure. The layer of signal interconnects of the first IC structure may be configured to provide signals to memory cells of, both, the first and the second IC structures.

### BACKGROUND

Memory is important to the performance of modern system-on-a-chip (SoC) technology. Low power and high-density memory is used in many different computer products and further improvements are always desirable.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 provides an electric circuit diagram of a one access transistor (1T) and one capacitor (1C) (1T-1C) memory cell, according to some embodiments of the present disclosure.

FIGS. 2A-2B are cross-sectional and plan views, respectively, of an example thin-film transistor (TFT) based memory cell with an access TFT, according to some embodiments of the present disclosure.

FIGS. 3A-3B are cross-sectional views of an example structure of the access TFT in the memory cell of FIGS. 2A-2B, according to some embodiments of the present disclosure.

FIGS. 4A-4B provide, respectively, a schematic illustration and a cross-sectional view of an example IC structure that may include memory and back-side power delivery, according to some embodiments of the present disclosure.

FIGS. 5A-5F provide cross-sectional views of example IC devices with stacks of IC structures with memory and back-side power delivery, according to some embodiments of the present disclosure.

FIGS. 6A-6F provide cross-sectional side views at different stages of fabricating an IC structure with memory and back-side power delivery, according to some embodiments of the present disclosure.

FIGS. 7A-7B provide cross-sectional views of example IC devices with stacks of IC structures with memory and back-side power delivery, according to some embodiments of the present disclosure.

FIGS. 8A-8B are top views of a wafer and dies that may include IC structures with memory and back-side power delivery, according to some embodiments of the present disclosure.

FIG. 9 is a cross-sectional side view of one side of an IC structure in which memory and back-side power delivery may be implemented, according to some embodiments of the present disclosure.

FIG. 10 is a cross-sectional side view of an IC package that may include one or more IC devices with stacks of IC structures with memory and back-side power delivery, according to some embodiments of the present disclosure.

FIG. 11 is a cross-sectional side view of an IC device assembly that may include one or more IC devices with stacks of IC structures with memory and back-side power delivery, according to some embodiments of the present disclosure.

FIG. 12 is a block diagram of an example computing device that may include one or more IC devices with stacks of IC structures with memory and back-side power delivery, according to some embodiments of the present disclosure.

### DETAILED DESCRIPTION

The systems, methods and devices of this disclosure each have several innovative aspects, no single one of which is solely responsible for all of the desirable attributes disclosed herein. Details of one or more implementations of the subject matter described in this specification are set forth in the description below and the accompanying drawings.

For purposes of illustrating IC devices with stacks of IC structures with memory and back-side power delivery as described herein, it might be useful to first understand phenomena that may come into play in certain IC arrangements. The following foundational information may be viewed as a basis from which the present disclosure may be properly explained. Such information is offered for purposes of explanation only and, accordingly, should not be construed in any way to limit the broad scope of the present disclosure and its potential applications.

Some memory devices may be considered “standalone” devices in that they are included in a chip that does not also include compute logic (where, as used herein, the term “compute logic devices” or simply “compute logic” or “logic devices,” refers to IC components, e.g., transistors, for performing computing/processing operations). Other memory devices may be included in a chip along with compute logic and may be referred to as “embedded” memory devices. Using embedded memory to support compute logic may improve performance by bringing the memory and the compute logic closer together and eliminating interfaces that increase latency. Various embodiments of the present disclosure relate to embedded memory arrays, as well as corresponding methods and devices.

Some embodiments of the present disclosure may refer to dynamic random-access memory (DRAM) and in particular, embedded DRAM (eDRAM), because this type of memory has been introduced in the past to address the limitation in density and standby power of other types or memory. However, embodiments of the present disclosure are equally applicable to memory implemented using other technologies. Thus, in general, memory described herein may be implemented as eDRAM cells, spin-transfer torque random-access memory (STTRAM) cells, resistive random-access memory (RRAM) cells, or any other nonvolatile memory cells.

As an example, a DRAM cell may include a capacitor for storing a bit value, or a memory state (e.g., logical “1” or “0”) of the cell, and an access transistor controlling access to the cell (e.g., access to write information to the cell or access to read information from the cell). Such a memory cell may be referred to as a “1T-1C memory cell,” highlighting the fact that it uses one transistor (i.e., “1T” in the term “1T-1C memory cell”) and one capacitor (i.e., “1C” in the term “1T-1C memory cell”). The capacitor of a 1T-1C memory cell may be coupled to one source or drain (S/D) terminal/region of the access transistor (e.g., to the source terminal/region of the access transistor), while the other S/D terminal/region of the access transistor (e.g., to the drain terminal/region) may be coupled to a bit-line (BL), and a gate terminal of the transistor may be coupled to a word-line (WL). Since such a memory cell can be fabricated with as little as a single access transistor, it can provide higher density and lower standby power versus some other types of memory in the same process technology.

In some implementations, 1T-1C memory cells are built with access transistors being front end of line (FEOL), logic-process based, transistors implemented in an upper-most layer of a semiconductor substrate. Such transistors may be referred to as front-end transistors or FEOL transistors. In other implementations, 1T-1C memory cells are built in the back-end of an IC device, e.g., with access transistors and capacitors being part of one or more back end of line (BEOL) layers that also include interconnect layers (also referred to as “metal layers”). Such memory cells, transistors, and capacitors may be referred to as “back-end” or “BEOL” memory cells, transistors, and capacitors.

Back-end memory may be implemented using TFTs as access transistors of the memory cells embedded in one or more BEOL layers. A TFT is a special kind of a field-effect transistor made by depositing a thin film of an active semiconductor material, as well as a dielectric layer and metallic contacts, over a supporting layer that may be a non-conducting layer and a non-semiconductor layer. At least a portion of the active semiconductor material forms a channel of the TFT. This is different from conventional, non-TFT, FEOL logic transistors where the active semiconductor channel material is typically a part of a semiconductor substrate, e.g., a part of a silicon wafer. Using TFTs as access transistors of memory cells provides several advantages and enables unique architectures that were not possible with conventional, FEOL logic transistors. For example, one advantage is that a TFT may have substantially lower leakage than a logic transistor, allowing to relax the demands on the large capacitance placed on a capacitor of a 1T-1C memory cell. In other words, using a lower leakage TFT in a 1T-1C memory cell allows the memory cell to use a capacitor with lower capacitance and smaller aspect ratio while still meeting the same data retention requirements of other approaches, alleviating the scaling challenges of capacitors.

Additionally, or alternatively, to TFT-based memory, back-end memory may be implemented using layer transfer to form access transistors of the memory cells embedded in the one or more BEOL layers. Layer transfer may include epitaxially growing a layer of a highly crystalline semiconductor material on another substrate and then transferring the layer, or a portion thereof, to embed it in the one or more BEOL layers provided over a second substrate. Channel regions of back-end transistors then include at least portions of such transferred semiconductor material layer. Performing layer transfer may advantageously allow forming non-planar transistors, such as FinFETs, nanowire transistors, or nanoribbon transistors, in the one or more BEOL layers. In some embodiments, transistors, or portions thereof (e.g., S/D regions) may be formed on the first substrate (i.e., on the substrate on which a layer of a highly crystalline semiconductor material is grown) before the layer transfer takes place, and then a layer with such transistors, or portions thereof, is transferred.

Layer transfer approach for providing memory may be particularly suitable for forming access transistors with channel regions formed of substantially single-crystalline semiconductor materials. On the other hand, TFT-based memory may be seen as an example of a monolithic integration approach because the semiconductor materials for the channel regions are deposited in one or more BEOL layers of an IC device, as opposed to being epitaxially grown elsewhere and then transferred, which may be particularly suitable for forming access transistors with channels formed of polycrystalline, polymorphous, or amorphous semiconductor materials, or various other thin-film channel materials. Whether a semiconductor material of a channel region for a given back-end device (e.g., a back-end transistor) has been provided by monolithic integration approach or by layer transfer can be identified by inspecting grain size of active semiconductor material of the device (e.g., of the semiconductor material of the channel region of a back-end transistor). An average grain size of the semiconductor material being between about 0.5 and 1 millimeters (in which case the material may be polycrystalline) or smaller than about 0.5 millimeter (in which case the material may be polymorphous) may be indicative of the semiconductor material having been deposited in the one or more BEOL layers of the device (i.e., monolithic integration approach), e.g., to form a TFT. On the other hand, an average grain size of the semiconductor material being equal to or greater than about 1 millimeter (in which case the material may be a single-crystal material) may be indicative of the semiconductor material having been included in the one or more BEOL layers of the device by layer transfer. The discussions of monolithic integration vs. layer transfer approaches for forming memory are equally applicable to back-end transistors that are not part of a memory array (e.g., if back-end transistors are implemented in an IC device to serve as logic transistors, switches, or for any other purposes or in any other circuits).

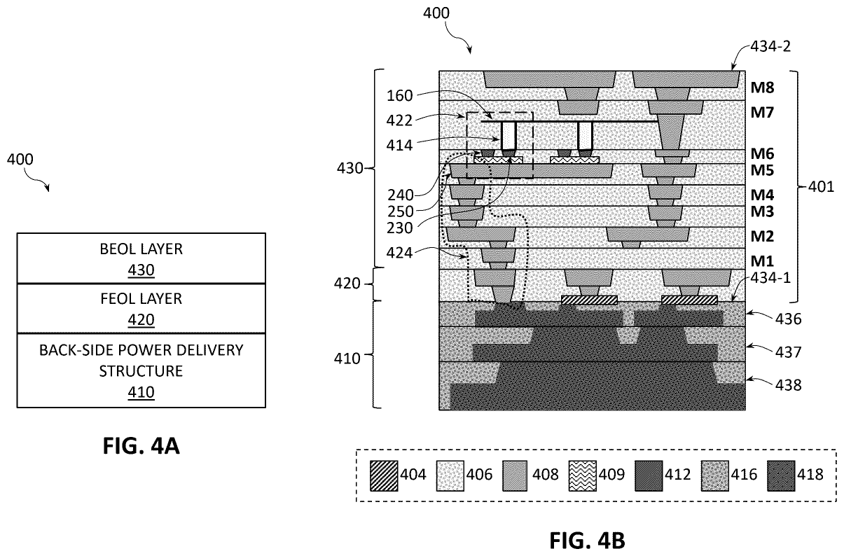

Moving access transistors to the BEOL layer of an advanced complementary metal oxide semiconductor (CMOS) process, either by monolithic integration (e.g., using TFTs) or by layer transfer, means that their corresponding capacitors can be implemented in the upper metal layers with correspondingly thicker interlayer dielectric (ILD) and larger metal pitch to achieve higher capacitance. This may ease the integration challenge introduced by embedding the capacitors. Furthermore, when at least some access transistors are implemented as back-end transistors, at least portions of different memory cells may be provided in different layers of BEOL above a substrate, thus enabling a stacked architecture of memory arrays. In this context, the term “above” refers to a layer in the BEOL being further away from the FEOL layer of an IC device (e.g., as shown in an IC structure 400 of FIGS. 4A-4B).

Continuous desire to decrease the size of electronic components dictates that the macro area of memory arrays continues to decrease, placing limitations on how large the top area (i.e., the footprint) of a given memory cell is allowed to be. Therefore, it would be desirable to stack multiple layers of memory cells above one another. However, providing power to more than a few layers of memory cells stacked above one another is not an easy task. Conventionally, power is provided from the front side of IC devices, i.e., a face of IC devices that is above the BEOL so that one or more of the BEOL layers are between said front side and the FEOL layer. Recently, power has been provided from the back side of IC devices, i.e., a face of IC devices that is below the FEOL layer, so that the FEOL layer is between said back side and the one or more BEOL layers. Providing power to memory cells from the back side is based on performing back-side reveal to remove some or all of the support structure over which the FEOL components (e.g., front-end transistors) were formed and then providing one or more layers of interconnects for routing power at the revealed back side. Providing power to memory from the back side of an IC device may provide advantages in terms of, e.g., easier fabrication and decreased complexity of power routing. Furthermore, when back-side power delivery is implemented, besides interconnects for delivering power, a back-side power delivery structure may include various IC components (e.g., capacitors, inductors, resistors, etc.) for reducing the parasitic effects of the assembly, e.g., for reducing parasitic effects associated with the interconnects used for power delivery. However, while providing power from the back side to a single layer of memory cells, or to a few layers of memory cells stacked above one another, may provide advantages over more conventional front side power delivery, providing power from the back side to more than a few layers of memory cells is still challenging in terms of routing of interconnects.

IC devices with stacks of IC structures with memory and back-end power delivery are disclosed, where different IC structures of a stack are bonded together, e.g., using hybrid bonding. Different IC structures may be fabricated on different dies and subsequently bonded together. Therefore, stacks of IC structures with memory and back-end power delivery, described herein, may also be referred to as stacks of dies with memory and back-end power delivery. In one aspect, an example IC device may include a first IC structure and a second IC structure. The first IC structure includes a layer of memory cells, a power delivery structure at the back side of the layer of memory cells, and a layer of signal interconnects at a front side of the layer of memory cells. The second IC structure is attached to the layer of signal interconnects of the first IC structure and includes a layer of memory cells and a power delivery structure at a back side of the layer of memory cells of the second IC structure. Embodiments of the present disclosure are based on recognition that bonding different IC structures together where each IC structure has a respective back-side power delivery structure may provide improvements in terms of routing power to multiple layers of memory cells. Embodiments of the present disclosure are further based on recognition that, when two IC structures, each with its own back-side power delivery structure, are bonded together to form a stack, bonding them in a specific orientation with respect to one another may be particularly advantageous. The particularly advantageous orientation includes two IC structures bonded so that the back-side power delivery structures are positioned at opposite ends of the stack (e.g., one at the bottom and one at the top). This arrangement may improve device performance because it ensures that the relatively high-capacitance power lines of the power delivery structures are kept away from the relatively low-capacitance data lines of a layer of signal interconnects in one of the IC structures. In some embodiments, the layer of signal interconnects of the first IC structure may be configured to provide signals to memory cells of, both, the first and the second IC structures. Thus, the layer of signal interconnects of the first IC structure may, advantageously, be shared among memory cells of the first IC structure and memory cells of the second IC structure.

In the following, some descriptions may refer to memory being TFT-based memory. However, embodiments of the present disclosure are equally applicable to memory implemented using layer transfer instead of, or in addition to, TFTs. Similarly, some descriptions may refer to memory being 1T-1C DRAM. However, embodiments of the present disclosure are equally applicable to other types of DRAM (e.g., DRAM where each memory cell includes one access transistor is coupled to multiple capacitors to increase the total storage capacity), or to memory other than DRAM instead of, or in addition to, 1T-1C DRAM.

Furthermore, some descriptions may refer to a particular S/D region or contact of a transistor being either a source region/contact or a drain region/contact. However, unless specified otherwise, which region/contact of a transistor is considered to be a source region/contact and which region/contact is considered to be a drain region/contact is not important because, as is common in the field of field-effect transistors (FETs), designations of source and drain are often interchangeable. Therefore, descriptions of some illustrative embodiments of the source and drain regions/contacts provided herein are applicable to embodiments where the designation of source and drain regions/contacts may be reversed. Unless explained otherwise, in some settings, the terms S/D region, S/D contact, and S/D terminal of a transistor may be used interchangeably, although, in general, the term “S/D contact” is used to refer to an electrically conductive structure for making a contact to a S/D region of a transistor, while the term “S/D terminal” may generally refer to either S/D region or S/D contact of a transistor.

Still further, while some descriptions provided herein may refer to transistors being bottom-gated transistors, embodiments of the present disclosure are not limited to only this design and include transistors of various other architectures, or a mixture of different architectures. For example, in various embodiments, transistors described herein, may include bottom-gated transistors, top-gated transistors, FinFETs, nanowire transistors, nanoribbon transistors, planar transistors, etc., all of which being within the scope of the present disclosure. Furthermore, although descriptions of the present disclosure may refer to logic devices or memory cells provided in a given layer of an IC device, each layer of the IC devices described herein may also include other types of devices besides logic or memory devices described herein. For example, in some embodiments, FEOL layers with logic transistors may also include memory cells and/or BEOL layers with memory cells may also include logic transistors. In general, a FEOL layer may include one or more layers, each including front-end components and/or interconnects, and a BEOL layer may include one or more layers, each including back-end components (e.g., memory) and/or interconnects.

In the following detailed description, various aspects of the illustrative implementations will be described using terms commonly employed by those skilled in the art to convey the substance of their work to others skilled in the art. For example, a term “interconnect” may be used to describe any element formed of an electrically conductive material for providing electrical connectivity to one or more components associated with an IC or/and between various such components. In general, the term “interconnect” may refer to both conductive lines (or, simply, “lines,” also sometimes referred to as “traces” or “trenches”) and conductive vias (or, simply, “vias”). In general, in context of interconnects, the term “conductive line” may be used to describe an electrically conductive element isolated by an insulator material (e.g., a low-k dielectric material) that is provided within the plane of an IC die. Such conductive lines are typically stacked into several levels, or several layers, of a metallization stack of the BEOL layers. On the other hand, the term “conductive via” may be used to describe an electrically conductive element that interconnects two or more lines of different levels. To that end, a conductive via may be provided substantially perpendicularly to the plane of an IC die and may interconnect two conductive lines in adjacent levels or two conductive lines in not adjacent levels. A term “metallization stack” may be used to refer to a stack of one or more interconnects for providing connectivity to different circuit components of an IC chip. Sometimes, conductive lines and vias may be referred to as “metal traces” and “metal vias”, respectively, to highlight the fact that these elements include electrically conductive materials such as metals.

In another example, the terms “package” and “IC package” are synonymous, as are the terms “die” and “IC die,” the term “insulating” means “electrically insulating,” the term “conducting” means “electrically conducting,” unless otherwise specified. Although certain elements may be referred to in the singular herein, such elements may include multiple sub-elements. For example, “an electrically conductive material” may include one or more electrically conductive materials. The term “insulating” and variations thereof (e.g., “insulative” or “insulator”) means “electrically insulating,” the term “conducting” and variations thereof (e.g., “conductive” or “conductor”) means “electrically conducting,” unless otherwise specified. For example, the term “insulator material” may refer to solid materials (and/or liquid materials that solidify after processing as described herein) that are substantially electrically non-conducting. They may include, as examples and not as limitations, organic polymers and plastics, and inorganic materials such as ionic crystals, porcelain, glass, silicon and alumina or a combination thereof. They may include dielectric materials, high polarizability materials, and/or piezoelectric materials. They may be transparent or opaque without departing from the scope of the present disclosure. If used, the terms “oxide,” “carbide,” “nitride,” etc. refer to compounds containing, respectively, oxygen, carbon, nitrogen, etc., the term “high-k dielectric” refers to a material having a higher dielectric constant than silicon oxide, while the term “low-k dielectric” refers to a material having a lower dielectric constant than silicon oxide. Furthermore, the term “connected” may be used to describe a direct electrical connection between the things that are connected (e.g., with the things being in electrically conductive and/or physical contact, e.g., in direct contact or directly electrical connected), without any intermediary devices, while the term “coupled” may be used to describe either a direct electrical or magnetic connection between the things that are connected, or an indirect connection through one or more passive or active intermediary devices. Describing A and B are being “in contact” includes A and B being in direct physical contact, possibly with an interface that may form when A and B are brough into direct physical contact with one another. The term “circuit” may be used to describe one or more passive and/or active components that are arranged to cooperate with one another to provide a desired function. The terms “substantially,” “close,” “approximately,” “near,” and “about,” generally refer to being within +/−20%, e.g., within +/−5% or within +/−2%, of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−20%, e.g., within +/−5% or within +/−2% of a target value based on the context of a particular value as described herein or as known in the art.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. As used herein, the notation “A/B/C”means (A), (B), and/or (C).

The description may use the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner.

In the following detailed description, reference is made to the accompanying drawings that form a part hereof wherein like numerals designate like parts throughout, and in which is shown, by way of illustration, embodiments that may be practiced. It is to be understood that other embodiments may be utilized, and structural or logical changes may be made, without departing from the scope of the present disclosure. Therefore, the following detailed description is not to be taken in a limiting sense.

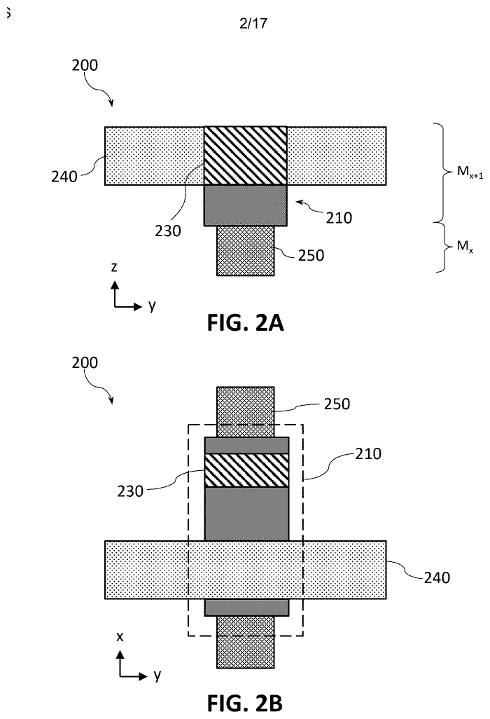

Any of the features discussed with reference to any of accompanying drawings herein may be combined with any other features to form stacks of IC structures with memory and back-side power delivery, as appropriate. A number of elements of the drawings are shared with others of the drawings; for ease of discussion, a description of these elements is not repeated, and these elements may take the form of any of the embodiments disclosed herein. For convenience, a collection of drawings labeled with letters may be referred to without letters (e.g., a collection of drawings shown in FIGS. 2A-2B may be referred to as FIG. 2).

The drawings are not necessarily to scale. In the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of presence of stacks of IC structures with memory and back-side power delivery as described herein.

Various IC devices with stacks of IC structures with memory and back-side power delivery as described herein may be implemented in, or associated with, one or more components associated with an IC or/and may be implemented between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

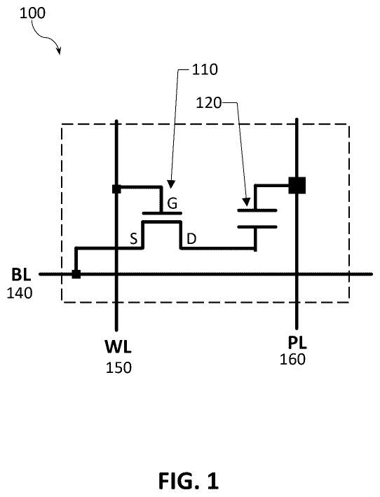

FIG. 1 provides an electric circuit diagram of an 1T-1C memory cell 100, according to some embodiments of the present disclosure. As shown, the 1T-1C cell 100 may include an access transistor 110 and a capacitor 120. The access transistor 110 has a gate terminal, a source terminal, and a drain terminal, indicated in the example of FIG. 1 as terminals G, S, and D, respectively. In the following, the terms “terminal” and “electrode/contact” may be used interchangeably. Furthermore, for S/D terminals, the terms “terminal” and “region”may be used interchangeably.

As shown in FIG. 1, in the 1T-1C cell 100, the gate terminal of the access transistor 110 may be coupled to a WL 150, one of the S/D terminals of the access transistor 110 may be coupled to a BL 140, and the other one of the S/D terminals of the access transistor 110 may be coupled to a first electrode of the capacitor 120. As also shown in FIG. 1, the other electrode of the capacitor 120 may be coupled to a capacitor plate-line (PL) 160 (also sometimes referred to as a “select-line” (SL)). As is known in the art, WL, BL, and PL may be used together to read and program the capacitor 120.

Each of the BL 140, the WL 150, and the PL 160, as well as intermediate elements coupling these lines to various terminals described herein, may be formed of any suitable electrically conductive material, which may include an alloy or a stack of multiple electrically conductive materials. In some embodiments, such electrically conductive materials may include one or more metals or metal alloys, with metals such as ruthenium, palladium, platinum, cobalt, nickel, hafnium, zirconium, titanium, tantalum, and aluminum. In some embodiments, such electrically conductive materials may include one or more electrically conductive alloys oxides or carbides of one or more metals.

In some embodiments, the access transistor 110 may be a TFT. In other embodiments, the access transistor 110 may be a transistor other than a TFT. For example, the access transistor 110 may be a transistor formed on a crystalline semiconductor material provided in the back end of an IC device using layer transfer, or it may be an FEOL transistor. In some such embodiments, the access transistor 110 may be a FinFET, a nanowire, or a nanoribbon transistor.

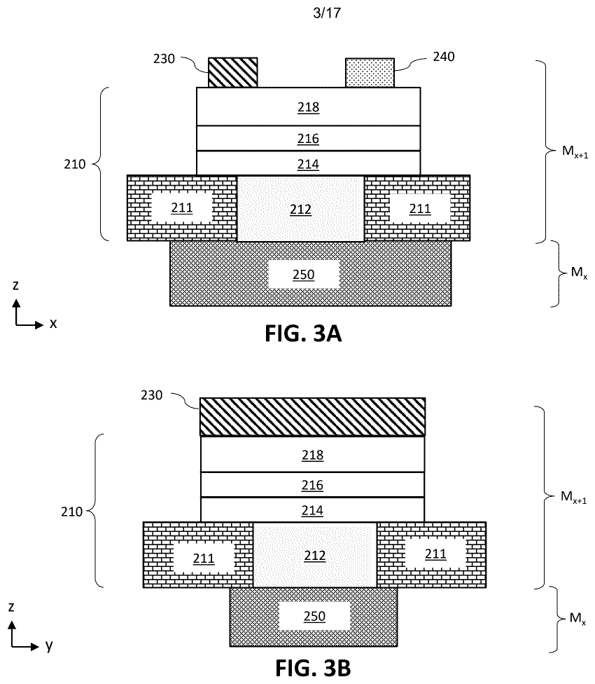

FIGS. 2A-2B are cross-sectional (y-z plane) and plan (y-x plane) views, respectively, of an example access TFT 210 of a given memory cell 200, according to some embodiments of the present disclosure. For example, the access TFT 210 may be the access transistor 110 of FIG. 1, and the memory cell 200 may be the memory cell 100 of FIG. 1. FIGS. 3A-3B are cross-sectional views (x-z and y-z planes) of an example structure of the access TFT 210 in the memory cell 200 of FIG. 2A-2B, according to some embodiments of the present disclosure. The memory cell 200 shown in FIGS. 2 and 3 is an example of a memory cell that may be implemented to realize one or more of the memory cells of the memory of an IC structure with memory and back-side power delivery as described herein, e.g., of IC devices 500 or 700 as described herein. In some embodiments of the IC devices 500 or 700 as described herein, multiple memory cells 200 may be arranged in a stacked architecture, i.e., when different memory cells such as the one shown in FIGS. 2 and 3 are stacked in different interconnect layers of the BEOL.

As shown in FIG. 2, the memory cell 200 may include a WL 250 (which may be an example of the WL 150 of FIG. 1) to supply a gate signal. As also shown in FIG. 2, the memory cell 200 may further include an access TFT 210 that includes a channel layer and is configured to control transfer of a memory state of the memory cell between a first region and a second region of the channel layer in response to the gate signal (channel layer and first and second regions described in greater detail below, e.g., with reference to FIG. 3). In some embodiments, the access TFT 210 may be provided above the WL 250 coupled to the memory cell 200. As also shown in FIG. 2, the memory cell 200 may further include a BL 240 to transfer the memory state and coupled to the first region of the channel layer of the access TFT 210, and a storage node 230 coupled to the second region of the channel layer of the access TFT 210. Although not specifically shown in FIG. 2, the memory cell 200 further includes a capacitor such as the capacitor 120 of FIG. 1, e.g., a metal-insulator-metal (MIM) capacitor coupled to the storage node 230 and configured to store the memory state of the memory cell 200.

Turning to the details of FIG. 2, the access TFT 210 in the memory cell 200 may be coupled to or controlled by WL 250, which, in some embodiments, may serve as the gate of the access TFT 210. A BL 240 (which may be an example of the BL 140 of FIG. 1) may be coupled to one of the S/D regions (or to one of the S/D contacts or terminals) of the access TFT 210 and a storage node 230 may be coupled to the other one of the S/D regions of the access TFT 210. In some embodiments, the BL 240 may serve as a first S/D contact (i.e., an electrically conductive structure for making a contact to a first S/D region of a transistor) and the storage node 230 may serve as the second S/D contact (i.e., an electrically conductive structure for making a contact to a second S/D region of a transistor) of the access TFT 210. The BL 240 may be connected to a sense amplifier and a BL driver which may, e.g., be provided in a memory peripheral circuit associated with a memory array that includes the memory cell 200. In some embodiments, for a given memory cell 200, the WL 250 may be formed in a metal layer Mx (where x is an integer indicating a specific layer) of the BEOL of an IC device, while the access TFT 210, the storage node 230, and the BL 240 may be formed in a metal layer Mx+1 of the BEOL of an IC device, i.e., the metal layer above the metal layer Mx, e.g., directly above the metal layer Mx (as illustrated in FIGS. 2 and 3). A capacitor of the memory cell 200 may then be formed in a metal layer Mx+2 of the BEOL of an IC device, e.g., directly above the metal layer Mx+1.

FIGS. 3A-3B illustrate further details of the access TFT 210. As shown in FIGS. 3A-3B, in some embodiments, the access TFT 210 may be provided substantially above the WL 250. In some embodiments, the access TFT 210 may be a bottom-gated TFT in that its gate stack comprising a gate dielectric 216 and a gate electrode 214 may be provided below its channel layer (also referred to as “active layer”) 218, e.g., between the channel layer 218 and the WL 250, and the channel layer 218 may be between the gate stack and the BL 240 forming one of the S/D terminals, e.g., the drain terminal, of the access TFT 210 and the storage node 230 forming another one of the S/D terminals, e.g., the source terminal, of the access TFT 210 (again, in other embodiments, this example designation of S/D terminals may be reversed). Thus, the WL 250 may be between a back-side power delivery structure 410 as shown in FIG. 4 and the gate electrode 214, and the BL 240 may be further away from the back-side power delivery structure 410 than the channel layer 218.

The channel layer 218 may be composed of semiconductor material systems including, for example, N-type or P-type materials systems. In some embodiments, the channel layer 218 may include a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, the channel layer 218 may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N-or P-type amorphous or polycrystalline silicon, germanium, indium gallium arsenide, silicon germanium, gallium nitride, aluminum gallium nitride, indium phosphite, and black phosphorus, each of which may possibly be doped with one or more of gallium, indium, aluminum, fluorine, boron, phosphorus, arsenic, nitrogen, tantalum, tungsten, and magnesium, etc. In particular, the channel layer 218 may be formed of a thin-film material. Some such materials may be deposited at relatively low temperatures, which allows depositing them within the thermal budgets imposed on back end fabrication to avoid damaging the front end components such as the logic devices of the FEOL layer of an IC structure 400 or an IC device 500. In some embodiments, the channel layer 218 may have a thickness between about 5 and 75 nanometers, including all values and ranges therein.

The S/D electrodes of the access TFT 210, shown in various figures as provided by the corresponding BL 240 and the storage node 230, respectively, may include any suitable electrically conductive material, alloy, or a stack of multiple electrically conductive materials. In some embodiments, the S/D electrodes of the access TFT 210 may include one or more metals or metal alloys, with metals e.g., copper, ruthenium, palladium, platinum, cobalt, nickel, hafnium, zirconium, titanium, tantalum, and aluminum, tantalum nitride, tungsten, doped silicon, doped germanium, or alloys and mixtures of these. In some embodiments, the S/D electrodes of the access TFT 210 may include one or more electrically conductive alloys, oxides, or carbides of one or more metals. In some embodiments, the S/D electrodes of the access TFT 210 may include a doped semiconductor, such as silicon or another semiconductor doped with an N-type dopant or a P-type dopant. Metals may provide higher conductivity, while doped semiconductors may be easier to pattern during fabrication. In some embodiments, the S/D electrodes of the access TFT 210 may have a thickness (i.e., dimension measured along the z-axis of the example coordinate system shown in the present drawings) between about 2 nanometers and 1000 nanometers, preferably between about 2 nanometers and 100 nanometers.

A gate dielectric 216 may laterally surround the channel layer 218, and the gate electrode 214 may laterally surround the gate dielectric 216 such that the gate dielectric 216 is disposed between the gate electrode 214 and the channel layer 218. In various embodiments, the gate dielectric 216 may include one or more high-k dielectric materials and may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric 216 may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In some embodiments, an annealing process may be carried out on the gate dielectric 216 during manufacture of the access TFT 210 to improve the quality of the gate dielectric 216. In some embodiments, the gate dielectric 216 may have a thickness between about 0.5 nanometers and 3 nanometers, including all values and ranges therein, e.g., between about 1 and 3 nanometers, or between about 1 and 2 nanometers.

In some embodiments, the gate dielectric 216 may be a multilayer gate dielectric, e.g., it may include any of the high-k dielectric materials in one layer and a layer of IGZO. In some embodiments, the gate stack (i.e., a combination of the gate dielectric 216 and the gate electrode 214) may be arranged so that the IGZO is disposed between the high-k dielectric and the channel layer 218. In such embodiments, the IGZO may be in contact with the channel layer 218, and may provide the interface between the channel layer 218 and the remainder of the multilayer gate dielectric 216. The IGZO may have a gallium to indium ratio of 1:1, a gallium to indium ratio greater than 1 (e.g., 2:1, 3:1, 4:1, 5:1, 6:1, 7:1, 8:1, 9:1, or 10:1), and/or a gallium to indium ratio less than 1 (e.g., 1:2, 1:3, 1:4, 1:5, 1:6, 1:7, 1:8, 1:9, or 1:10).

The gate electrode 214 may include at least one P-type work function metal or N-type work function metal, depending on whether the access TFT 210 is a P-type metal oxide semiconductor (PMOS) transistor or an N-type metal oxide semiconductor (NMOS) transistor. For a PMOS transistor, metals that may be used for the gate electrode 214 may include, but are not limited to, ruthenium, palladium, platinum, cobalt, nickel, and conductive metal oxides (e.g., ruthenium oxide). For an NMOS transistor, metals that may be used for the gate electrode 214 include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate electrode 214 may include a stack of two or more metal layers, where one or more metal layers are work function metal layers and at least one metal layer is a fill metal layer. Further metal layers may be included for other purposes, such as to act as a diffusion barrier layer, described below.

FIGS. 3A-3B further illustrate that the access TFT 210 implemented as a bottom-gated access TFT may further, optionally, include layers such as a diffusion barrier 212, which may be surrounded by a layer of etch-resistant material (e.g., an etch-stop layer 211). In some embodiments, the diffusion barrier 212 may be a metal-or copper-diffusion barrier (e.g., a conductive material to reduce or prevent the diffusion of metal or copper from WL 250 into the gate electrode 214 while still maintaining an electrical connection between the WL 250 and the gate electrode 214) on the WL 250 such as TaN, tantalum (Ta), titanium zirconium nitride (e.g., TiXZr1-XN, such as X=0.53), titanium nitride (e.g., TiN), titanium tungsten (TiW), combination (such as a stack structure of TaN on Ta), or the like. For instance, the diffusion barrier 212 can include a single-or multilayer structure including a compound of tantalum(Ta) and nitrogen(n), such as TaN or a layer of TaN on a layer of Ta. In some embodiments, a layer of an etch-resistant material (e.g., the etch-stop layer 211) such as silicon nitride or silicon carbide may be formed over the WL 250 with vias for a metal (or copper) diffusion barrier 212 such as TaN or a TaN/Ta stack. The gate electrode 214 can be a conductive material on the diffusion barrier 212, such as metal, conductive metal oxide or nitride, or the like. For example, in one embodiment, the gate electrode 214 may be titanium nitride (TiN). In another embodiment, the gate electrode 214 may be tungsten (W).

The channel layer 218 can be in contact with the BL 240 (e.g., at a first S/D region of the channel layer 218, e.g., a drain region) and with the storage node 230 (e.g., at a second S/D region of the channel layer 218, e.g., a source region, with a semiconducting channel region of the access TFT 210 being between the first S/D region and the second S/D region). In some embodiments, such a channel region may include only majority carriers in the thin film. Accordingly, the channel layer 218 may require a relatively high bias (as e.g., supplied by the WL 250, diffusion barrier 212, and gate electrode 214) to activate.

FIGS. 4A-4B provide, respectively, a schematic illustration and a cross-sectional view of an example IC structure 400 that may include memory and back-side power delivery, according to some embodiments of the present disclosure.

As shown in FIG. 4A, the IC structure 400 may include an FEOL layer 420 and a BEOL layer 430 above the FEOL layer 420, where each of the FEOL layer 420 and the BEOL layer 430 may include one or more layers. As also shown in FIG. 4A, the IC structure 400 may further include a back-side power delivery structure 410, so that the FEOL layer 420 is between the back-side power delivery structure 410 and the BEOL layer 430. The FEOL layer 420 and/or the BEOL layer 430 may include at least one layer of memory, e.g., a memory array with a plurality of 1T-1C memory cells as described herein, e.g., memory cells 100/200 as described herein, or a stack of such layers/arrays.

The FEOL layer 420 may include a plurality of FEOL devices, e.g., front-end transistors such as FinFETs, nanowire transistors, nanoribbon transistors, etc. In some embodiments, some or all of the front-end transistors may be implemented as transistors with back-side S/D contacts. In some embodiments, some or all of the front-end transistors may be implemented as transistors with front-side S/D contacts. In general, a transistor is described as a transistor with front-side S/D contacts if both S/D contacts of the transistor are on one side of a channel material of the transistor, above the channel material of the transistor. On the other hand, a transistor is described as a transistor with back-side S/D contacts if either both S/D contacts of the transistor are below the channel material of the transistor or if one S/D contact is on one side with respect to the channel material (e.g., above the channel material) and the other S/D contact is on the opposite side (e.g., below the channel material).

The BEOL layer 430 may include a plurality of back-end interconnects electrically coupled to (e.g., in electrically conductive contact with at least portions of) one or more of the plurality of FEOL devices of the FEOL layer 420 and/or one or more of the plurality of memory cells of the memory.

In some embodiments, the front-end transistors implemented in the FEOL layer 420 may be a part of compute logic, e.g., to serve as a memory peripheral circuit for the memory arrays implemented in the BEOL layer 430. For example, the front-end transistors may be responsible for compute logic functionality related to read/write operations with respect to the data stored in the memory cells that may be implemented in the BEOL layer 430. To that end, some of the front-end transistors of the FEOL layer 420 may be part of one or more input/output (I/O) ICs (e.g., a memory peripheral circuit) configured to control (e.g., control access (read/write), store, refresh) the memory cells implemented in the IC structure 400 (e.g., memory cells implemented in the BEOL layer 430). In some embodiments, some of the front-end transistors of the FEOL layer 420 may be part of high-performance compute logic, configured to perform various operations with respect to data stored in the memory cells implemented in the IC structure 400 (e.g., arithmetic and logic operations, pipelining of data from one or more of the memory arrays implemented in the IC structure 400, and possibly also data from external devices/chips). In some embodiments of the IC structure 400, the compute logic may be provided in the FEOL layer 420 and in one or more lowest metal layer of the BEOL layer 430, while one or more memory arrays may be provided in higher layers of the BEOL layer 430. In other embodiments of the IC structure 400, the compute logic described with reference to the FEOL layer 420 may be provided above the FEOL layer 420 (e.g., in the BEOL layer 430), in between memory layers of the BEOL layer 430, or combined with the memory layers of the BEOL layer 430.

Various interconnect layers of the BEOL layer 430 may be/include metal layers of a metallization stack of the IC structure 400. Various metal layers of the BEOL layer 430 may be used to interconnect the various inputs and outputs of the logic devices in the compute logic and/or of the memory cells in the memory layers of the FEOL layer 420 and/or of the BEOL layer 430. Generally speaking, each of the metal layers of the BEOL layer 430 may include a conductive via portion and a conductive trench/interconnect portion. The conductive trench portion of a metal layer is configured for transferring signals and power along electrically conductive (e.g., metal) lines (also sometimes referred to as “trenches”) extending in the x-y plane (e.g., in the x or y directions), while the conductive via portion of a metal layer is configured for transferring signals and power through electrically conductive vias extending in the z-direction, e.g., to any of the adjacent metal layers above or below. Accordingly, conductive vias connect metal structures (e.g., metal lines or vias) from one metal layer to metal structures of an adjacent metal layer. While referred to as “metal” layers, various layers of the BEOL layer 430 may include only certain patterns of conductive metals, e.g., copper (Cu), aluminum (Al), tungsten (W), or cobalt (Co), or metal alloys, or more generally, patterns of an electrically conductive material, formed in an insulating medium such as an ILD. The insulating medium may include any suitable ILD materials such as silicon oxide, carbon-doped silicon oxide, silicon carbide, silicon nitride, aluminum oxide, and/or silicon oxynitride.

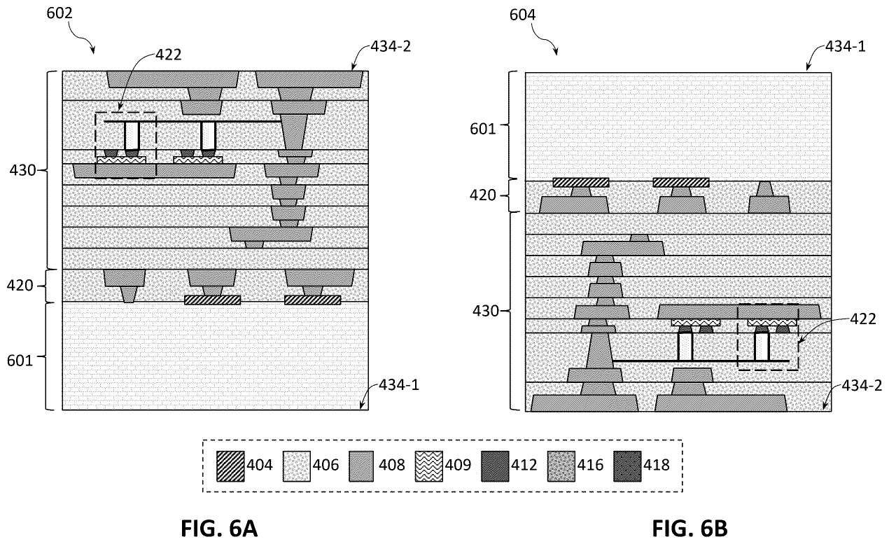

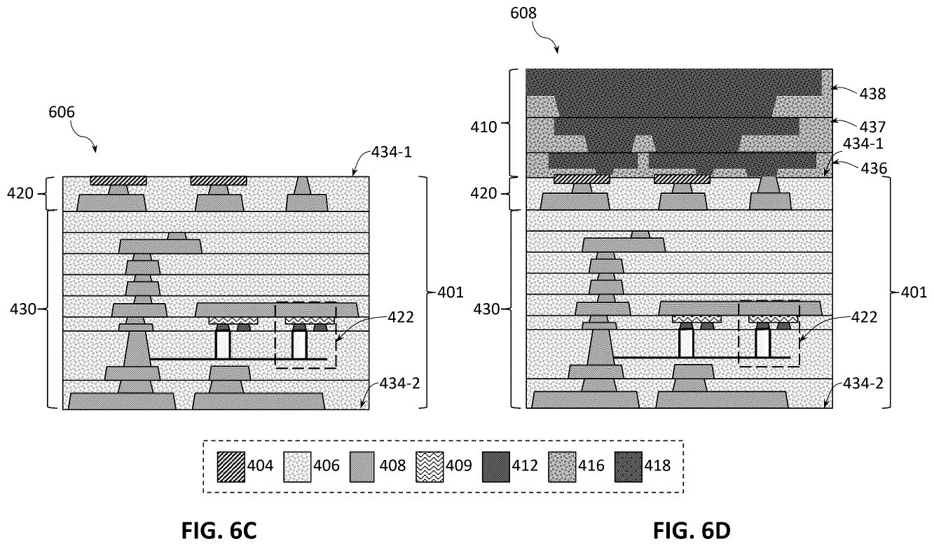

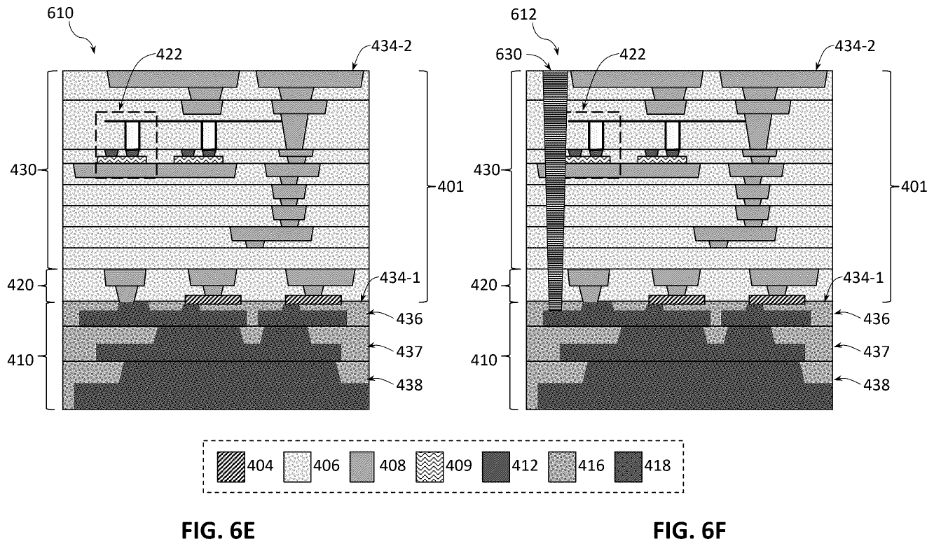

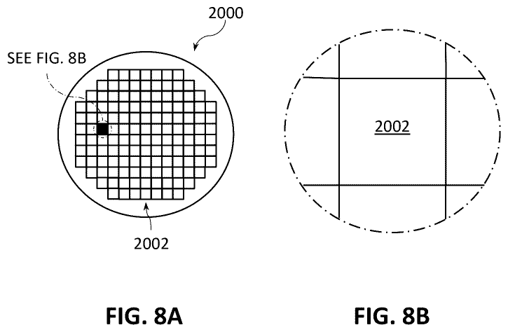

The FEOL layer 420 may originally be provided over a semiconductor support structure such as a substrate, a die, a wafer or a chip. Such a semiconductor support structure may, e.g., be a support structure 601 of FIG. 6A, or a wafer 2000 of FIG. 8A, discussed below.

While the FEOL layer 420 may originally be provided over a semiconductor support structure as described above, such a semiconductor support structure may subsequently be removed to expose the back-side portions of the FEOL devices of the FEOL layer 420 so that a back-side power delivery structure 410 may be provided at the back side of the FEOL layer 420 (thus, the BEOL layer 430 are provided at the front side of the FEOL layer 420 and the back-side power delivery structure 410 is provided at the back side of the FEOL layer 420). The back-side power delivery structure 410 may include a plurality of interconnects (i.e., metal lines and vias) configured to provide power to one or more devices (e.g., logic transistors and/or memory cells) of the FEOL layer 420 and to one or more devices (e.g., logic transistors and/or memory cells) of the BEOL layer 430. In some embodiments, the back-side power delivery structure 410 may further include various IC components (e.g., capacitors, inductors, resistors, etc.) for reducing the parasitic effects of the IC structure 400, e.g., for reducing parasitic effects associated with the interconnects used for power delivery.

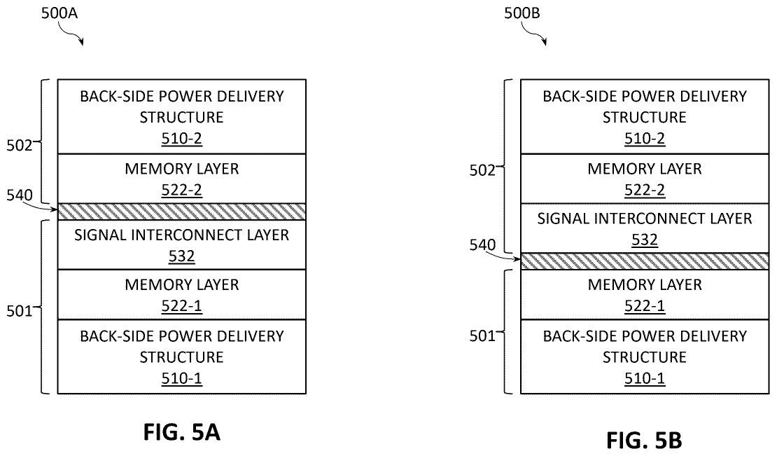

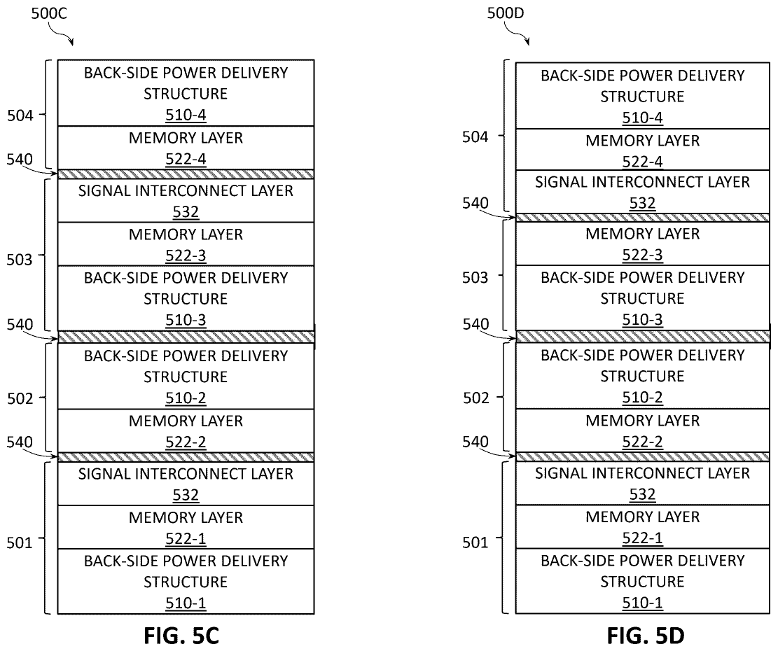

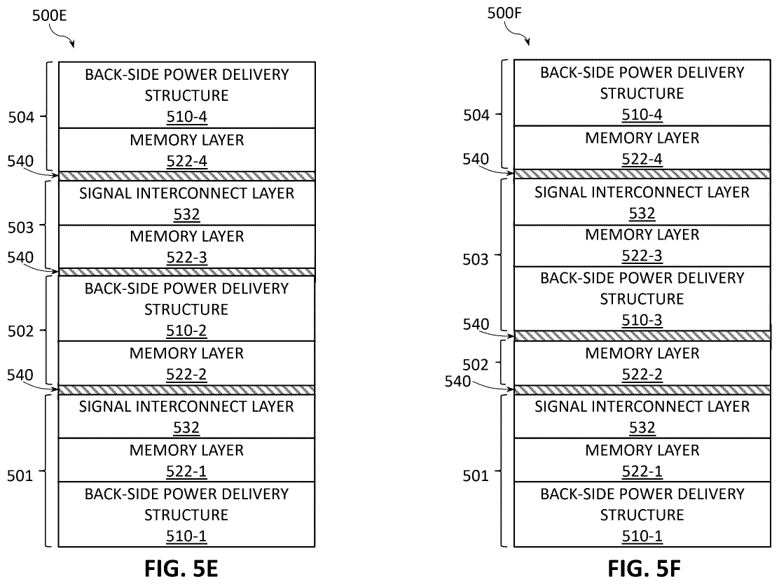

Providing power from the back side of an IC device as shown in FIG. 4A may be advantageous in terms of easier fabrication and decreased complexity of power routing to memory implemented in the FEOL layer 420 and/or the BEOL layer 430. In addition, when an IC device is a combination of multiple IC structures bonded together, especially where some of the IC structures have their front sides bonded to other IC structures, providing power from the back side of such IC structures may be the only option possible. For example, in some embodiments, an IC device may include a first IC structure bonded with a second IC structure in a front-to-front (f2f) arrangement. Examples of such IC device are shown as IC devices 500A and 500B of FIGS. 5A and 5B.

FIG. 4B provides a cross-sectional view of the IC structure 400 according to some embodiments of the present disclosure. A number of elements labeled in FIG. 4B and in at least some of the subsequent figures with reference numerals are illustrated in these figures with different patterns, with a legend showing the correspondence between the reference numerals and patterns being provided at the bottom of each drawing page containing these figures. For example, the legend illustrates that FIG. 4B uses different patterns to show front-end transistors 404, an ILD material 406, interconnects 408, etc. Furthermore, although a certain number of a given element may be illustrated in FIG. 4B and in at least some of the subsequent figures (e.g., FIGS. 6-8), this is also simply for ease of illustration, and more, or less, than that number may be included in an IC structure or an IC device according to various embodiments of the present disclosure. Still further, FIG. 4B and in at least some of the subsequent figures (e.g., FIGS. 6-8) are intended to show relative arrangements of various elements in example stacks of IC structures with memory and back-side power delivery, and that various IC structures with memory and back-side power delivery and IC devices with stacks of IC structures with memory and back-side power delivery, or portions thereof, may include other elements or components that are not illustrated (e.g., any further materials, such as spacer materials that may surround the gate stack of the transistors, etch-stop materials, etc.).

The IC structure 400 shown in FIG. 4B is an example implementation of the IC structure 400 shown in FIG. 4A, which is indicated in FIG. 4B by labeling the back-side power delivery structure 410, the FEOL layer 420, and the BEOL layer 430 on the left side of FIG. 4B. As shown in FIG. 4B, in some embodiments, the FEOL layer 420 may include front-end devices, e.g., front-end transistors 404. The details of the front-end transistors 404 are not shown in FIG. 4B because various architectures of such transistors are known and the front-end transistors 404 may include a transistor of any architecture as known in the art. The channel regions of the front-end transistors 404 may include a semiconductor material that may originally be a portion of the support structure of the IC structure 400, which is later removed and replaced by the back-side power delivery structure 410.

FIG. 4B illustrates an ILD material 406 and a plurality of interconnects 408 above the front-end transistors 404. In various embodiments, the ILD material 406 may include any suitable ILD materials such as silicon oxide, carbon-doped silicon oxide, silicon carbide, silicon nitride, aluminum oxide, and/or silicon oxynitride. In various embodiments, the ILD material 406 may include any of the low-k dielectric materials described above. In various embodiments, the interconnects 408 may include any of the electrically conductive materials described above.

A portion of the ILD material 406 directly above and surrounding portions of the front-end transistors 404, and one or more of the interconnects 408 in that portion of the ILD material 406 may be seen as a part of the FEOL layer 420, whereas everything above may be seen as a part of the BEOL layer 430, as labeled in FIG. 4B. In particular, the BEOL layer 430 may include a metallization stack of a plurality of metal layers labeled in FIG. 4B as a metal layer 1 (M1), a metal layer 2 (M2), and so on. Although not specifically shown in FIG. 4B, a layer of an etch-stop(ES) material may be present between at least portions of adjacent metal layers of the BEOL layer 430. Such an ES material may include silicon and nitrogen, in some embodiments.

In some embodiments, even when only a single layer of memory cells is implemented, the memory may occupy a plurality of consecutive metal layers of the metallization stack of an IC device. This is shown in FIG. 4B with the memory being in the metal layers M5, M6, and M7. In particular, FIG. 4B illustrates access transistors 409, S/D contacts 412 for the access transistors 409, and capacitors 414. FIG. 4B further provides a label for a memory cell 422, illustrated in FIG. 4B within a dashed rectangular contour, that includes one access transistor 409 and one capacitor 414, coupled to one of the S/D contacts 412 of the access transistor 409. Thus, the memory cell 422 is an example of a 1T-1C memory cell, e.g., the memory cell 100 as described above, where the access transistor 409 is an example of the access transistor 110, and the capacitor 414 is an example of the capacitor 120, described above. In particular, the access transistor 409 is a back-end transistor and the memory cell 422 is a back-end memory cell in the example shown in FIG. 4B. Two such memory cells 422 are shown in FIG. 4B, but only one is labeled with reference numerals in order to not clutter the drawing. The memory cell 422 may be a memory cell according to any of the embodiments described above, e.g., an eDRAM memory cell as explained with reference to FIGS. 1-3. For example, as shown in FIG. 4B, in some embodiments of the memory cell 422, one of the interconnects 408 in a metal layer M5 may form a control line such as the WL 250, described above, while the access transistor 409, a storage node such as the storage node 230, and a control line such as the BL 240 may be formed in a metal layer M6 of the BEOL layer 430 (i.e., the metal layer directly above the metal layer M5), and the capacitor 414 may then be formed in a metal layer M7 (i.e., the metal layer directly above the metal layer M6). FIG. 4B further illustrates a control line such as the PL 160, described above, which may be coupled to one of the interconnects 408 in the metal layer M7. In other embodiments of the IC structure 400B, memory with memory cells as the memory cell 422 may be implemented in other metal layers of the BEOL layer 430, any number of memory cells 422 may be included in a given layer/array of memory cells, and multiple layers of memory cells such as the memory cell 422 may be stacked over one another, thus implementing three-dimensional (3D) stacked memory.

Together, the FEOL layer 420 and the BEOL layer 430 of the IC structure 400 may be seen as a part of an IC structure portion 401 in which a support structure on which the front-end transistors 404 were built has been removed and replaced by the back-side power delivery structure 410. To that end, a back side 434-1 and a front side 434-2 of the IC structure portion 401 may be defined as shown in FIG. 4B, illustrating that the back side 434-1 is the side where the support structure was removed and the back-side power delivery structure 410 was provided, and illustrating that the front side 434-2 is the face of the IC structure portion 401 that is opposite the back side 434-2, e.g., the upper surface of the BEOL layer 430.

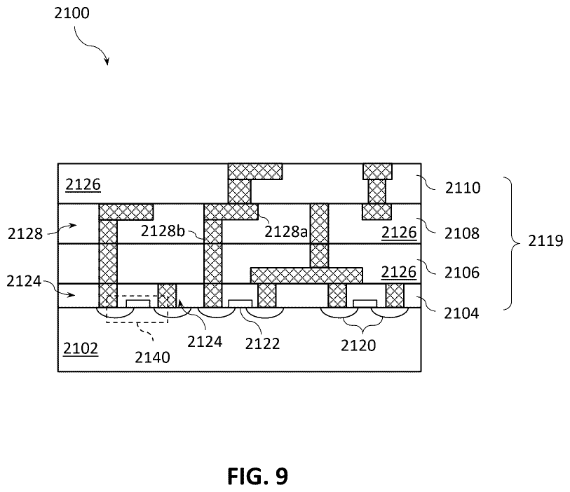

Turning to the details of the back-side power delivery structure 410 of the IC structure 400, FIG. 4B illustrates that the back-side power delivery structure 410 may include a back-side insulator 416 and a plurality of back-side interconnects 418 that may be coupled to any of the memory cells 422 of the memory implemented in the BEOL layer 430 in order to provide power to the memory. In some embodiments, the back-side interconnects 418 may also be coupled to the front-end transistors 404, to provide power to those components as well. The back-side interconnects 418 may include any suitable back-side interconnect structures, such as trench structures and/or via structures, e.g., as described below with reference to the interconnect structures 2128, shown in FIG. 9. In some embodiments, the back-side interconnects 418 may be arranged within back-side interconnect layers 436, 437, and 438 to route electrical signals to/from the memory in the BEOL layer 430 according to a wide variety of designs (in particular, the arrangement is not limited to the particular configuration of the back-side interconnects 418 depicted in FIG. 4B or other drawings). Although a particular number of interconnect layers 436, 437, and 438 in which the back-side interconnects 418 are disposed is depicted in FIG. 4B and in other drawings, embodiments of the present disclosure include IC devices having more or fewer interconnect layers 436, 437, and 438 with the back-side interconnects 418 than depicted. The interconnect layers 436, 437, and 438 may be similar to the interconnect layers 2106, 2108, 2110 shown in FIG. 9, but at the back side of the IC structure.

In some embodiments, the back-side interconnects 418 may be coupled to a given memory cell 422 by an electrical feedthrough network 424 of the interconnects 408, as is shown in FIG. 4B (i.e., a back-side interconnect 418 may be coupled to a memory cell 422 via a plurality of the interconnects 408 within a dotted contour labeled in FIG. 4B with the reference numeral “424”). In other embodiments, the back-side interconnects 418 may be coupled to a given memory cell 422 by a conductive via, not shown in FIG. 4B but shown as a conductive via 630 in an analogous IC structure of FIG. 6F, that may, e.g., extend from a front side 434-2 of the IC structure 400 towards and reaching the back side 434-1 and further extending into the back-side insulator 416 to make an electrical contact with at least one back-side interconnect 418, and where such a conductive via may be coupled to the memory cell 422. In various embodiments of the IC structure 400 as shown in FIG. 4B, any of the memory cells 422 may be coupled by any of the back-side interconnects 418 using any manner of coupling, such as the electrical feedthrough network 424 as shown in FIG. 4B or the conductive via 630, or by any combination of the electrical feedthrough networks 424 and one or more of the conductive vias such as the conductive via 630.

In various embodiments, the interconnects 408, the back-side interconnects 418, and the conductive via 630 may be implemented as known in the art. For example, in some embodiments, any of the interconnects 408, the back-side interconnects 418, and the c conductive via 630 may include an electrically conductive fill material and, optionally, a liner. The electrically conductive fill material may include one or more of copper, tungsten, aluminum, ruthenium, cobalt, etc. (e.g., in proportions of between 1:1 to 1:100), or any of the electrically conductive materials described above. The liner may be an adhesion liner and/or a barrier liner. For example, the liner may be a liner having one or more of tantalum, tantalum nitride, titanium nitride, tungsten carbide, cobalt, etc. In the liner and/or in the electrically conductive fill material of any of the interconnects 408, the back-side interconnects 418, and the conductive via 630, any of the individual materials (e.g., any of the examples listed above) may be included in the amount of between about 1% and 75%, e.g., between about 5% and 50%, indicating that these materials are included by intentional alloying of materials, in contrast to potential accidental doping or impurities being included, which would be less than about 0.1% for any of these metals. In general, material compositions of liners and/or electrically conductive fill materials of any of the interconnects 408, the back-side interconnects 418, and the conductive via 630 may, but do not have to be, the same. The back-side insulator 416 may include any of the materials described with reference to the ILD material 406, where, in general, material compositions of the back-side insulator 416 and the ILD material 406 may, but do not have to be, the same.

FIGS. 5A-5F provide cross-sectional views of example IC devices 500 (labeled in individual ones of FIGS. 5A-5F as IC devices 500A, 500B, 500C, 500D, 500E, and 500F) with stacks of IC structures with memory and back-side power delivery, according to some embodiments of the present disclosure.

As shown in FIG. 5A, an IC device 500A may include a first IC structure 501 that includes a back-side power delivery structure 510-1, a memory layer 522-1, and a signal interconnect layer 532, where the memory layer 522-1 may be between the back-side power delivery structure 510-1 and the signal interconnect layer 532. The IC device 500A may further include a second IC structure 502 that includes a back-side power delivery structure 510-2, and a memory layer 522-2. The IC device 500A may further include a bonding interface 540 between the first IC structure 501 and the second IC structure 502. In particular, the first IC structure 501 and the second IC structure 502 of the IC device 500A are bonded in a f2f arrangement because the bonding interface 540 is between the front side of the first IC structure 501 (i.e., the upper surface of the signal interconnect layer 532) and the front side of the second IC structure 502 (i.e., the upper surface of the memory layer 522-2), as is shown in FIG. 5A. Because the front sides of the first IC structure 501 and the second IC structure 502 are used for bonding, their respective back-side power delivery structures 510-1 and 510-2 may, advantageously, be used at the back sides of each of these IC structures to provide power to various components of the first IC structure 501 and the second IC structure 502. Thus, as shown in FIG. 5A, the signal interconnect layer 532 may be between the memory layer 522-1 and the bonding interface 540, while the bonding interface 540 may be between the signal interconnect layer 532 and the memory layer 522-2.

In some embodiments, average dimensions of the interconnects 408, in particular average dimensions of the interconnects 408 above the memory cell 422, may be smaller than average dimensions of the back-side interconnects 418 for each of the first IC structure 501 and the second IC structure 502 of the IC device 500A. Lower dimensions of interconnects may lead to lower capacitance between the metal lines of these interconnects. Therefore, the arrangement of the IC device 500A may improve device performance because it ensures that the relatively high-capacitance power lines of the power delivery structures 510-1 and 510-2 are kept away from the relatively low-capacitance data lines of the signal interconnect layer 532 of the first IC structure 501. Thus, in some embodiments, average dimensions of the interconnects 408 of the signal interconnect layer 532 may be smaller than average dimensions of the interconnects 418 of the back-side power delivery structure 510-1 of the first IC structure 501 and smaller than average dimensions of the interconnects 418 of the power delivery structures 510-2 of the second IC structure 502.

In the IC device 500A, the back-side power delivery structure 510-1 and the back-side power delivery structure 510-2 are examples of the back-side power delivery structure 410, described above. Furthermore, the memory layer 522-1 and the memory layer 522-2 are examples of memory that may be implemented in the FEOL layer 420 and/or the BEOL layer 430, as described above. The signal interconnect layer 532 may include any suitable network of interconnects for communicating signals, e.g., data to read and write, from/to memory cells of the memory layer 522-1 and the memory layer 522-2. For example, the signal interconnect layer 532 may include a plurality of interconnects above the memory layer 522-1, such as the interconnects of metal layers M7 and M8 shown in FIG. 4B.

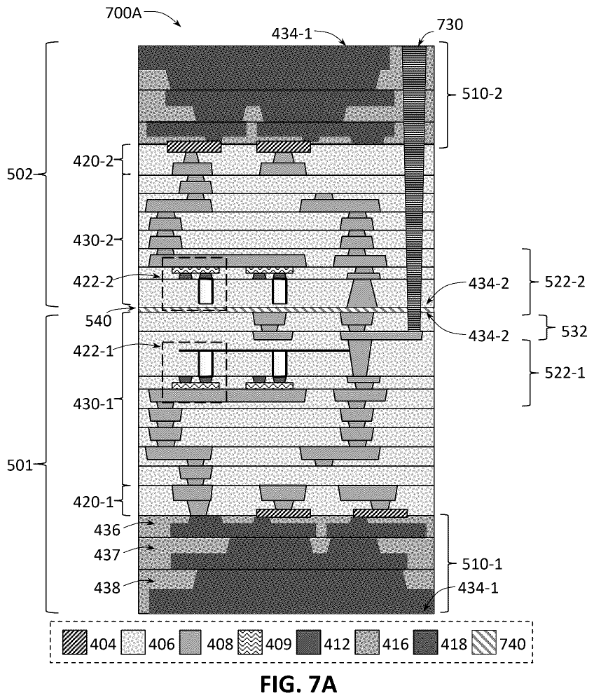

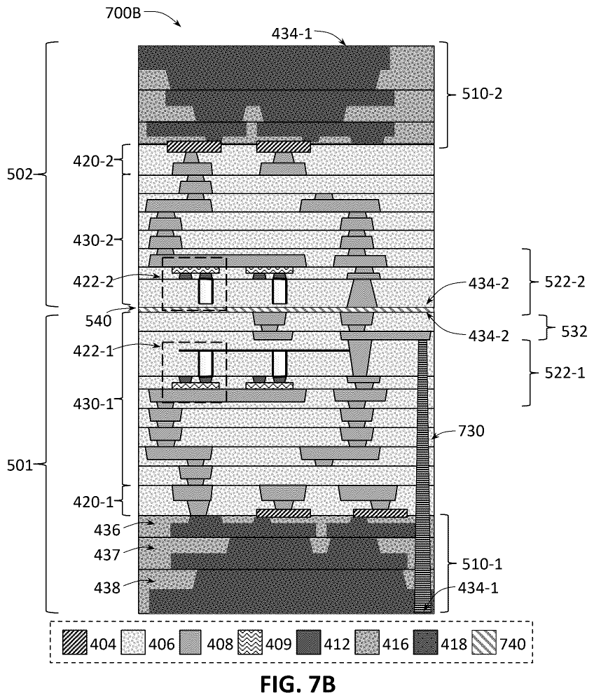

In general, bonding of the first IC structure 501 and the second IC structure 502 may be performed as follows. First, the first IC structure 501 and the second IC structure 502 may be fabricated individually. In some embodiments, they may be fabricated at different manufacturing facilities, by different companies, etc. After that, the front side of the first IC structure 501 and the front side of the second IC structure 502 may be bonded. In some embodiments, bonding of the faces of the front sides of the first IC structure 501 and the second IC structure 502 may be performing using insulator-insulator bonding, e.g., as oxide-oxide bonding, where an insulating material of the front side of the first IC structure 501 is bonded with an insulating material of the front side of the second IC structure 502 and where conductive contacts are provided through the bonding interface 540, to electrically connect conductive portions/contacts at the front side of the first IC structure 501 and conductive portions/contacts at the front side of the second IC structure 502. In some embodiments, a bonding material (e.g., a bonding material 740, shown in FIGS. 7A-7B), may be present in between at least portions of the faces of the IC structures 501 and 502 that are bonded together.

The IC device 500B, shown in FIG. 5B, is substantially the same as the IC device 500A, except that the signal interconnect layer 532 is part of the second IC structure 502, instead of the first IC structure 501. Thus, in the IC device 500B, the first IC structure 501 and the second IC structure 502 are still bonded in a f2f arrangement where the bonding interface 540 is between the memory layer 522-1 at the front side of the first IC structure 501 and the signal interconnect layer 532 at the front side of the second IC structure 502, as is shown in FIG. 5A. Similar to the IC device 500A, the arrangement of the IC device 500B may improve device performance because it ensures that the relatively high-capacitance power lines of the power delivery structures 510-1 and 510-2 are kept away from the relatively low-capacitance data lines of the signal interconnect layer 532 of the second IC structure 502.

In further embodiments, stacks of two IC structures as shown in FIG. 5A or FIG. 5B may be stacked together. One example of that is shown with the IC device 500C, shown in FIG. 5C, illustrating a stack of two IC devices 500A. The first stack of the IC device 500C is the stack of the first IC structure 501 and the second IC structure 502 and is substantially the same as the IC device. On top of that stack the same stack is attached, including a third IC structure 503 and a fourth IC structure 504 stacked in the same manner as the first IC structure 501 and the second IC structure 502. Thus, in the IC device 500C, besides what was already explained with reference to FIG. 5A, the following features are present. The third IC structure 503 is analogous to the first IC structure 501 of FIG. 5A and includes a back-side power delivery structure 510-3, a memory layer 522-3, and a signal interconnect layer 532, where the memory layer 522-3 may be between the back-side power delivery structure 510-3 and the signal interconnect layer 532. The fourth IC structure 504 is analogous to the second IC structure 502 of FIG. 5A and includes a back-side power delivery structure 510-4, and a memory layer 522-4. Another bonding interface 540 is between the third IC structure 503 and the fourth IC structure 504, similar to the bonding interface 540 between the first IC structure 501 and the second IC structure 502 of FIG. 5A. In the IC device 500C, the third IC structure 503 and the fourth IC structure 504 are bonded in a f2f arrangement, similar to the first IC structure 501 and the second IC structure 502 of the IC device 500A, where the bonding interface 540 is between the signal interconnect layer 532 at the front side of the third IC structure 503 and the memory layer 522-4 at the front side of the fourth IC structure 504 and, as is shown in FIG. 5C. A third bonding interface 540 bonds the top of the stack of the first IC structure 501 and the second IC structure 502 and the bottom of the stack of the third IC structure 503 and the fourth IC structure 504. Thus, in the IC device 500C, a bonding interface 540 is present between the back-side power delivery structure 510-2 of the second IC structure 502 and the back-side power delivery structure 510-3 of the third IC structure 503. The arrangement of the IC device 500C may improve device performance because it ensures that the relatively high-capacitance power lines of the power delivery structures 510-1, 510-2, 510-3, and 510-4 are kept away from the relatively low-capacitance data lines of the signal interconnect layer 532 of the first IC structure 501 and of the signal interconnect layer 532 of the third IC structure 503.

In the IC device 500C, the back-side power delivery structure 510-3 and the back-side power delivery structure 510-4 are examples of the back-side power delivery structure 410, described above. Furthermore, the memory layer 522-3 and the memory layer 522-4 are examples of memory that may be implemented in the FEOL layer 420 and/or the BEOL layer 430, as described above. The signal interconnect layer 532 of the IC device 500C is as described with reference to the IC device 500A.

The IC device 500D, shown in FIG. 5D, is substantially the same as the IC device 500C, except that the third IC structure 503 is analogous to the first IC structure 501 of the IC device 500B and the fourth IC structure 504 is analogous to the second IC structure 502 of the IC device 500B. In other words, FIG. 5D also illustrates a stack of two IC devices with two IC structures in each, but, while FIG. 5C illustrates a stack of two IC devices 500A, FIG. 5D illustrates a stack of the IC device 500A and the IC device 500B. Thus, in the IC device 500D, besides what was already explained with reference to FIG. 5A, FIG. 5B, and FIG. 5C, the following features are present. The third IC structure 503 is analogous to the first IC structure 501 of FIG. 5B and includes the back-side power delivery structure 510-3 and the memory layer 522-3. The fourth IC structure 504 is analogous to the second IC structure 502 of FIG. 5B and includes the back-side power delivery structure 510-4, the memory layer 522-4, and the signal interconnect layer 532, where the memory layer 522-4 is between the signal interconnect layer 532 of the fourth IC structure 504 and the back-side power delivery structure 510-4. Another bonding interface 540 is between the third IC structure 503 and the fourth IC structure 504, similar to the bonding interface 540 between the first IC structure 501 and the second IC structure 502 of FIG. 5B. In the IC device 500D, the third IC structure 503 and the fourth IC structure 504 are bonded in a f2f arrangement, similar to the first IC structure 501 and the second IC structure 502 of the IC device 500B, where the bonding interface 540 is between the memory layer 522-3 at the front side of the third IC structure 503 and the signal interconnect layer 532 at the front side of the fourth IC structure 504, as is shown in FIG. 5D. Similar to FIG. 5C, a third bonding interface 540 bonds the top of the stack of the first IC structure 501 and the second IC structure 502 and the bottom of the stack of the third IC structure 503 and the fourth IC structure 504. Thus, in the IC device 500D, a bonding interface 540 is present between the back-side power delivery structure 510-2 of the second IC structure 502 and the back-side power delivery structure 510-3 of the third IC structure 503, similar to the IC device 500C. The arrangement of the IC device 500D may improve device performance because it ensures that the relatively high-capacitance power lines of the power delivery structures 510-1, 510-2, 510-3, and 510-4 are kept away from the relatively low-capacitance data lines of the signal interconnect layer 532 of the first IC structure 501 and of the signal interconnect layer 532 of the fourth IC structure 504.

The IC device 500E, shown in FIG. 5E, is substantially the same as the IC device 500C, except that the back-side power delivery structure 510-3 is absent from the IC device 500E and, instead the bonding interface 540 is between the power delivery structures 510-2 of the second IC structure 502 and the memory layer 522-3 of the third IC structure 503. In this manner, the power delivery structures 510-2 of the second IC structure 502 may be shared between the memory layer 522-2 and the memory layer 522-3 (e.g., the power delivery structures 510-2 of the second IC structure 502 may be used to provide power to both the memory layer 522-2 and the memory layer 522-3).

The IC device 500F, shown in FIG. 5F, is also substantially the same as the IC device 500C, except that the back-side power delivery structure 510-2 is absent from the IC device 500F and, instead the bonding interface 540 is between the power delivery structures 510-2 of the second IC structure 502 and the memory layer 522-3 of the third IC structure 503. In this manner, the power delivery structures 510-3 of the third IC structure 503 may be shared between the memory layer 522-2 and the memory layer 522-3 (e.g., the power delivery structures 510-3 of the third IC structure 503 may be used to provide power to both the memory layer 522-2 and the memory layer 522-3).

Further variations and modifications to stacking of multiple stacks of two IC structures in line with the considerations described above are possible and are within the scope of the present disclosure.

IC devices with stacks of IC structures with memory and back-side power delivery, as described herein, may be fabricated using any suitable techniques, e.g., subtractive, additive, damascene, dual-damascene, etc. Some of such technique may include suitable deposition and patterning techniques. As used herein, “patterning” may refer to forming a pattern in one or more materials using any suitable techniques (e.g., applying a resist, patterning the resist using lithography, and then etching the one or more material using dry etching, wet etching, or any appropriate technique).

FIGS. 6A-6F provide cross-sectional side views at different stages of fabricating an IC structure with memory and back-side power delivery (e.g., the IC structure 400 described with reference to FIGS. 4A-4B or any one of the IC structures 510 described with reference to FIGS. 5A-5F), according to some embodiments of the present disclosure. The example fabrication method shown in FIGS. 6A-6F may include other operations not specifically shown in FIGS. 6A-6F, such as various cleaning or planarization operations as known in the art. For example, in some embodiments, any of the layers of the IC device may be cleaned prior to, after, or during any of the processes of the fabrication method described herein, e.g., to remove oxides, surface-bound organic and metallic contaminants, as well as subsurface contamination. In some embodiments, cleaning may be carried out using e.g., a chemical solutions (such as peroxide), and/or with ultraviolet (UV) radiation combined with ozone, and/or oxidizing the surface (e.g., using thermal oxidation) then removing the oxide (e.g., using hydrofluoric acid (HF)). In another example, the top surfaces of the IC devices described herein may be planarized prior to, after, or during any of the processes of the fabrication method described herein, e.g., to remove overburden or excess materials. In some embodiments, planarization may be carried out using either wet or dry planarization processes, e.g., planarization be a chemical mechanical planarization (CMP), which may be understood as a process that utilizes a polishing surface, an abrasive and a slurry to remove the overburden and planarize the surface.

The fabrication method may begin with a process 602, shown in FIG. 6A, that includes providing a support structure 601, forming the FEOL layer 420 on the support structure 601, and then forming the BEOL layer 430 with memory over the FEOL layer 420. The FEOL layer 420 and the BEOL layer 430 provided in the process 602 may be as those described above. The support structure 601 may include any suitable material or structure upon which the FEOL layer 420 may be provided. As shown in FIG. 6A, as a result of performing the process 602, the back side 434-1 is the back side of the support structure 601, and the front side 434-2 is the top surface of the BEOL layer 430.

In some embodiments, the support structure 601 may be a semiconductor support structure, e.g., a semiconductor substrate, composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the substrate may be non-crystalline. In some embodiments, the substrate may be a printed circuit board (PCB) substrate. Although a few examples of materials from which the substrate may be formed are described here, any material that may serve as a foundation upon which the FEOL layer 420 as described herein may be built falls within the spirit and scope of the present disclosure. In various embodiments, channel materials of the front-end transistors 404 of the FEOL layer 420 may include, or may be formed upon, any such substrate material.

In some embodiments, the channel material of the front-end transistors 404 of the FEOL layer 420 may be composed of semiconductor material systems including, for example, N-type or P-type materials systems. In some embodiments, the channel material of the front-end transistors 404 may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, the channel material of the front-end transistors 404 may include a combination of semiconductor materials where one semiconductor material may be used for the channel portion and another material, sometimes referred to as a “blocking material,” may be used between the channel portion and the support structure over which the front-end transistors are provided. In some embodiments, the channel material of the front-end transistors 404 may include a monocrystalline semiconductor, such as silicon (Si) or germanium (Ge). In some embodiments, the channel material of the front-end transistors 404 may include a compound semiconductor with a first sub-lattice of at least one element from group III of the periodic table (e.g., Al, Ga, In), and a second sub-lattice of at least one element of group V of the periodic table (e.g., P, As, Sb).

For some example N-type transistor embodiments (i.e., for the embodiments where a given front-end transistor 404 is an NMOS), the channel portion of the front-end transistor 404 may advantageously include a III-V material having a high electron mobility, such as, but not limited to InGaAs, InP, InSb, and InAs. For some such embodiments, the channel portion may be a ternary III-V alloy, such as InGaAs, GaAsSb, InAsP, or InPSb. For some InₓGa₁₋ₓAs fin embodiments, In content (x) may be between 0.6 and 0.9, and may advantageously be at least 0.7 (e.g., In_{0.7}Ga_{0.3}As). In some embodiments with highest mobility, the channel portion may be an intrinsic III-V material, i.e., a III-V semiconductor material not intentionally doped with any electrically active impurity. In alternate embodiments, a nominal impurity dopant level may be present within the channel portion, for example to further fine-tune a threshold voltage Vt, or to provide HALO pocket implants, etc. Even for impurity-doped embodiments however, impurity dopant level within the channel portion of the front-end transistors 404 may be relatively low, for example below 10¹⁵ dopant atoms per cubic centimeter (cm⁻³), and advantageously below 10¹³ cm⁻³.

For some example P-type transistor embodiments (i.e., for the embodiments where a given front-end transistor 404 is a PMOS), the channel portion of the front-end transistor 404 may advantageously be a group IV material having a high hole mobility, such as, but not limited to Ge or a Ge-rich SiGe alloy. For some example embodiments, the channel portion may have a Ge content between 0.6 and 0.9, and advantageously may be at least 0.7. In some embodiments with highest mobility, the channel portion may be intrinsic III-V (or IV for P-type devices) material and not intentionally doped with any electrically active impurity. In alternate embodiments, one or more a nominal impurity dopant level may be present within the channel portion of the front-end transistors 404, for example to further set a threshold voltage (Vt), or to provide HALO pocket implants, etc. Even for impurity-doped embodiments however, impurity dopant level within the channel portion is relatively low, for example below 10¹⁵ cm⁻³, and advantageously below 10¹³ cm⁻³.

The fabrication method may then proceed with a process 604, shown in FIG. 6B, that includes turning the IC device fabricated in the process 602 over so that further processing may be performed on the back side 434-1. Thus, FIG. 6B illustrates the same IC device as that shown in FIG. 6A, except that the back side 434-1 is now facing upwards and the front side 434-2 is at the bottom.

Next, the fabrication method may proceed with a process 606, shown in FIG. 6C, that includes removing the support structure 601. In some embodiments, the process 606 may include any suitable grinding or polishing process to reduce the thickness of the support structure 601. In some embodiments, grinding may be performed until the S/D regions of the front-end transistors 404 are exposed, as is shown in the present drawings and, in particular, in FIG. 6C. However, in other embodiments, a portion of the support structure 601 may remain above the front-end transistors 404 (not shown in the present drawings), i.e., the S/D regions of the transistors of the front-end transistors 404 may not necessarily be exposed as long as the back-side interconnects 418 may later be provided so as to electrically couple to the memory as described herein. As a result of performing the process 606, the back side 434-1 of the IC structure portion 401 is moved closer to the front side 434-2, compared to the result of performing the process 604.

The fabrication method may then proceed with a process 608, shown in FIG. 6D, that includes forming the back-side power delivery structure 410 on the back side 434-1 of the IC structure portion 401.

The fabrication method may then proceed with a process 610, shown in FIG. 6E, that includes turning the IC device fabricated in the process 608 over so that, if needed, further processing may be performed on the front side 434-2. Thus, FIG. 6E illustrates the same IC device as that shown in FIG. 6D, except that the front side 434-2 is now facing upwards and the back side 434-1 is at the bottom.

The fabrication method may then proceed with a process 612, shown in FIG. 6F, that includes providing a conductive via 630 that extends from the front side 434-2 towards and reaching the back side 434-1 and further extending into the back-side insulator 416 to make an electrical contact with at least one back-side interconnect 418. The conductive via 630 may be configured to couple (e.g., directly electrically connect) at least one back-side interconnect 418 and one or more of the memory cells 422.

FIGS. 7A-7B provide cross-sectional views of example IC devices 700 (labeled in individual ones of FIGS. 7A-7B as IC devices 700A and 700B) with stacks of IC structures with memory and back-side power delivery, according to some embodiments of the present disclosure. In particular, each of the IC devices 700A-700B is an example of the IC device 500A of FIG. 5A that includes a stack of the first IC structure 501 and the second IC structure 502, where each of the first IC structure 501 and the second IC structure 502 is implemented as the IC structure 400 of FIG. 4. Therefore, FIGS. 7A-7B use the same reference numerals as those used in FIG. 4 and in FIG. 5A to illustrate elements/components described above and their descriptions are not repeated. As can be seen in FIGS. 7A-7B, each of the IC devices 700A-700B is an f2f-bonded assembly of the IC structures 501 and 502 because the front side 434-2 of the second IC structure 502 is bonded to the front side 434-2 of the first IC structure 501. Thus, in an f2f-bonded assembly, one of the IC structures 501, 502 is flipped upside down for bonding so that the top face of the flipped IC structure is facing and is bonded to the top face of the IC structure that is not flipped.

What is further illustrated in FIGS. 7A-7B is that a bonding material 740 may be present at the bonding interface 540 between the first IC structure 501 and the second IC structure 502. The bonding material 740 may be applied to at least portions of the one or both front faces of the IC structures 501 and 502 that are to be bonded, and then the front faces of the IC structures 501 and 502 are put together, possibly while applying a suitable pressure and heating up the assembly to a suitable temperature (e.g., to moderately high temperatures, e.g., between about 50 and 200 degrees Celsius) for a duration of time. In some embodiments, the bonding material 740 may be an adhesive material that ensures attachment of the IC structures 501 and 502 to one another. In some embodiments, the bonding material 740 may be an ES material. In some embodiments, the bonding material 740 may be both an ES material and have suitable adhesive properties to ensure attachment of the IC structures 501 and 502 to one another. In other embodiments, no bonding material may be used, in which case the bonding material 740 in FIGS. 7A-7B and other drawings may represent a bonding interface 540 resulting from the bonding of the IC structures 501 and 502 to one another. The bonding interface 540 may be recognizable as a seam or a thin layer in the IC devices 500, using, e.g., selective area diffraction (SED), even when the specific materials of the insulators of the IC structures 501 and 502 that are bonded together may be the same, in which case the bonding interface 540 would still be noticeable as a seam or a thin layer in what otherwise appears as a bulk insulator (e.g., bulk oxide) layer. As used herein, unless specified otherwise, references to the “bonding material 740” are applicable to a “bonding interface” for the embodiments where no deliberately added adhesive material is used to bond the IC structures 501 and 502.

Although not specifically shown in FIGS. 7A-7B, any embodiments of the IC devices 700A-700B as described herein may further include one or more ES materials that may be included in the first IC structure 501, e.g., between some or all pairs of metal layers of a metallization stack of the first IC structure 501, and/or in the second IC structure 502, e.g., between some or all pairs of metal layers of a metallization stack of the second IC structure 502. Such layers of ES materials are commonly used in the field of semiconductor manufacturing and may be provided at different locations of the IC structures 501, 502, the locations being dependent on, e.g., specific processing techniques used to manufacture portions of these IC structures. In some embodiments, because the IC structures 501, 502 may be fabricated by different manufacturers, using different materials, or different manufacturing techniques, the material compositions of their ES materials may be different. For example, the ES material included in the first IC structure 501 may include a material with silicon and nitrogen (e.g., silicon nitride), while the ES material included in the second IC structure 502 may include a material with silicon and carbon (e.g., silicon carbide), or one of the ES materials included in the IC structures 501, 502 may include a material with aluminum and oxygen (e.g., aluminum oxide). Furthermore, the bonding material 740 at the interface between the IC structures 501 and 502 may have a material composition different from one or both of the ES material included in the first IC structure 501 and the ES material included in the second IC structure 502. For example, in some embodiments, the bonding material 740 may include silicon, nitrogen, and carbon, where the atomic percentage of any of these materials may be at least 1%, e.g., between about 1% and 50%, indicating that these elements are added deliberately, as opposed to being accidental impurities which are typically in concentration below about 0.1%. Having both nitrogen and carbon in these concentrations in addition to silicon is not typically used in conventional semiconductor manufacturing processes where, typically, either nitrogen or carbon is used in combination with silicon, and, therefore, would be a characteristic feature of the hybrid manufacturing as described herein. Using an ES material at the interface between the IC structures 501 and 502 that includes include silicon, nitrogen, and carbon, where the atomic percentage of any of these materials may be at least 1%, e.g., SiOCN, may be advantageous in terms that such a material may act both as an ES material, and have sufficient adhesive properties to bond the IC structures 501 and 502 together. In addition, an ES material at the interface between the IC structures 501 and 502 that includes include silicon, nitrogen, and carbon, where the atomic percentage of any of these materials may be at least 1%, may be advantageous in terms of improving etch-selectivity of this material with respect to the ES materials of the IC structures 501 and 502.

As shown in FIGS. 7A-7B, the back-side power delivery structure 510-1 is provided on the back side 434-1 of the first IC structure 501 and may be configured to provide power to various components of the first IC structure 501. Similarly, the power delivery structures 510-2 is provided on the back side 434-1 of the second IC structure 502 and may be configured to provide power to various components of the first IC structure 502. While power may be provided to various components of the IC structures 501, 502 from their respective back-side power delivery structures 510-1, 510-2, the signal interconnect layer 532 is part of the first IC structure 501 and is shared between the IC structures 501, 502. In order to provide signals/data to the shared signal interconnect layer 532 of the IC devices 700A-700B, an after-bonding via 730 may be provided, the after-bonding via 730 configured to couple one or more of the interconnects 408 of the signal interconnect layer 532, and, therefore, in turn couple to the memory cells 422 of the memory layer 522-1 and to the memory cells 422 of the memory layer 522-2. As shown in FIG. 7A, in some embodiments, the after-bonding via 730 may extend from the back side 434-1 of the second IC structure 502 towards and reaching the front side 434-2 of the second IC structure 502, extending through the bonding interface 540, and further extending from the front side 434-2 of the first IC structure 501, through the ILD material 406 of the first IC structure 501, to make an electrical contact with at least one of the interconnects 408 of the signal interconnect layer 532 of the first IC structure 501. In various embodiments, the after-bonding via 730 may be implemented as described above for the interconnects 408, the back-side interconnects 418, and the via 630. FIG. 7B illustrates an IC device that is substantially the same as that shown in FIG. 7A, except where the after-bonding via 730 may extend from the back side 434-1 of the first IC structure 501 towards but not reaching the front side 434-2 of the first IC structure 501, to make an electrical contact with at least one of the interconnects 408 of the signal interconnect layer 532 of the first IC structure 501.

Because of different fabrication processes being performed on different sides of the IC structures 501, 502, and on different sides of the IC devices 700A-700B, in some embodiments, IC devices 700A-700B may exhibit characteristic features indicative of the fabrication processes. In particular, for certain manufacturing processes, cross-sectional shapes of various interconnects in the planes such as that shown in FIGS. 7A-7B may be substantially trapezoidal, i.e., a cross-section of an interconnect may have two parallel sides, one of which is a short side and another one of which is a long side. For example, dual-Damascene or single-Damascene processes for manufacturing interconnects could result in such trapezoidal cross-sections. Therefore, examining the trapezoidal cross-sectional shapes of the interconnects 408, the back-side interconnects 418, and the after-bonding via 730 may reveal characteristic features of the fabrication processes used to manufacture the IC devices 700A-700B. For example, for the IC device 700A, for the each of the cross-section of the conductive via 730, the cross-section of the at least one of the back-side interconnects 418 of the first power delivery structure 510-1, and the cross-section of the at least one of the back-side interconnects 418 of the second power delivery structure 510-2, the short side may be closer to the bonding interface 540 than the long side. For the IC device 700B, for the each of the cross-section of the conductive via 730, the cross-section of the at least one of the back-side interconnects 418 of the first power delivery structure 510-1, and the cross-section of the at least one of the back-side interconnects 418 of the second power delivery structure 510-2, the short side may also be closer to the bonding interface 540 than the long side, as in the IC device 700A, but, in the IC device 700B, the after-bonding via 730 is flipped upside down compared to the IC device 700A. For each of the IC devices 700A-700B, for the cross-section of the at least one of the interconnects 408 of the signal interconnect layer 532, the long side may be closer to the bonding interface 540 than the short side, because the signal interconnect layer 532 is part of the first IC structure 501.

IC devices with stacks of IC structures with memory and back-side power delivery as disclosed herein may be included in any suitable electronic device. FIGS. 8-12 illustrate various examples of devices and components that may include one or more IC devices with stacks of IC structures with memory and back-side power delivery as disclosed herein, e.g., one or more IC devices 500, one or more IC devices 700, any further embodiments of the IC devices 500 and 700 disclosed herein, and any combination of any embodiments of the IC devices 500 and 700.

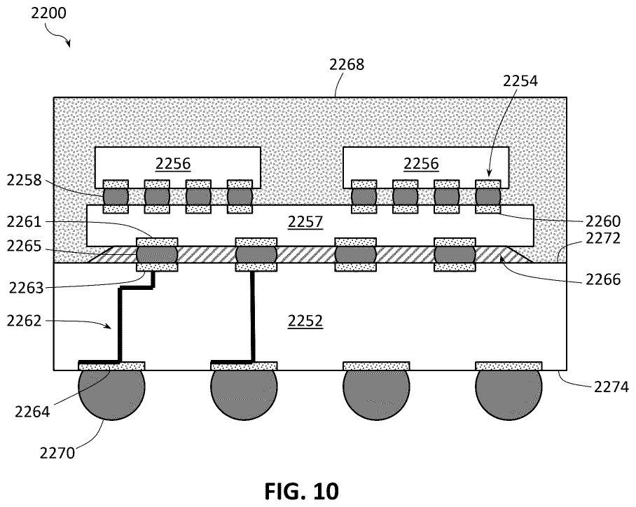

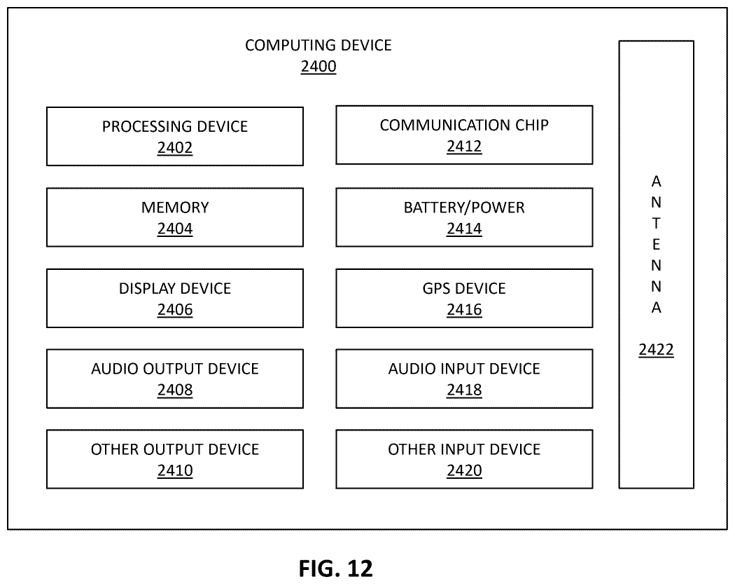

FIGS. 8A-8B are top views of a wafer 2000 and dies 2002 that may include one or more IC structures with memory and back-side power delivery for later inclusion in IC devices with stacks of IC structures with memory and back-side power delivery, according to some embodiments of the present disclosure. In some embodiments, the dies 2002 may be included in an IC package, according to some embodiments of the present disclosure. For example, any of the dies 2002 may be part of any of the dies or die arrangements 2256 in an IC package 2200 shown in FIG. 10. The wafer 2000 may be composed of semiconductor material and may include one or more dies 2002 having IC structures formed on a surface of the wafer 2000. Each of the dies 2002 may be a repeating unit of a semiconductor product that includes any suitable IC (e.g., IC structures with memory and back-side power delivery as described herein). After the fabrication of the semiconductor product is complete (e.g., after manufacture of one or more IC structures with memory and back-side power delivery as described herein, e.g., any embodiment of the IC structures included in IC devices with stacks of IC structures with memory and back-side power delivery as described herein), the wafer 2000 may undergo a singulation process in which each of the dies 2002 is separated from one another to provide discrete “chips” of the semiconductor product. In particular, devices that include IC structures with back-side reveal for power delivery to memory as disclosed herein may take the form of the wafer 2000 (e.g., not singulated) or the form of the die 2002 (e.g., singulated). The die 2002 may include one or more transistors (e.g., one or more front-end transistors 404 and one or more transistors 409 as described herein and/or one or more front-end transistors 2140 of FIG. 9, discussed below), one or more memory cells (e.g., one or more 1T-1C memory cells or any other memory cells as described herein, e.g., one or more memory cells 422 and/or one or more memory layers 522-1, 522-2), and/or supporting circuitry (e.g., one or more interconnects as described herein) to route electrical signals to the transistors and/or the memory cells, as well as any other IC components. In some embodiments, the wafer 2000 or the die 2002 may implement or include a memory device, a logic device (e.g., an AND, OR, NAND, or NOR gate), or any other suitable circuit element. Multiple ones of these devices may be combined on a single die 2002. For example, a memory array formed by multiple memory cells in a given layer may be formed on a same die 2002 as a processing device (e.g., the processing device 2402 of FIG. 12) or other logic that is configured to store information in the memory devices or execute instructions stored in the memory array.

FIG. 9 is a cross-sectional side view of one side of an IC structure 2100 in which memory and back-side power delivery may be implemented, according to some embodiments of the present disclosure. For example, the IC structure 2100 may form basis for fabricating any of the IC structures 400, 501, 502, 503, or 504, described above, i.e., may form basis for fabricating IC devices with stacks of IC structures with memory and back-side power delivery as described herein. In particular, the memory as described herein may be implemented in any of the back-end layers of the IC structure 2100, e.g., in any of the interconnect layers 2106, 2108, 2110 shown in FIG. 9, or in any of the front-end layers of the IC structure 2100, e.g., alongside with the transistors 2140. Because there are various possibilities where such memory may be integrated in the IC structure 2100, the memory is not specifically shown in FIG. 9. In some embodiments, the IC structure 2100 may serve as part of any of the dies or die arrangements 2256 in the IC device assembly 2300.

As shown in FIG. 9, the IC structure 2100 may include a back-side power delivery structure 2102 on the back side of one or more device layers 2104. The back-side power delivery structure 2102 may be implemented as the back-side power delivery structure 410, described above. The device layers 2104 provide one example of one or more layers with the front-end transistors 404 of the FEOL layer 420, described above. The device layer 2104 may include features of one or more transistors 2140 (e.g., metal oxide semiconductor field-effect transistors (MOSFETs)) formed on a substrate which is subsequently thinned and replaced with the back-side power delivery structure 2102. The transistors 2140 provide one example of any of the front-end transistors 404, described above. The device layer 2104 may include, for example, one or more S/D regions 2120, a gate 2122 to control current flow in the transistors 2140 between the S/D regions 2120, and one or more S/D contacts 2124 to route electrical signals to/from the S/D regions 2120. The transistors 2140 may include additional features not depicted for the sake of clarity, such as device isolation regions, gate contacts, and the like.

Each transistor 2140 may include a gate 2122 formed of at least two layers, a gate dielectric layer and a gate electrode layer. Generally, the gate dielectric layer of a transistor 2140 may include one layer or a stack of layers, and may include any of the materials described above with reference to the gate dielectric 216. In some embodiments, an annealing process may be carried out on the gate dielectric of the gate 2122 to improve its quality when a high-k material is used.

The gate electrode may be formed on the gate dielectric and may include at least one P-type work function metal or N-type work function metal, depending on whether the transistor 2140 is to be a PMOS or an NMOS transistor. In some implementations, the gate electrode may include a stack of two or more metal layers, where one or more metal layers are work function metal layers and at least one metal layer is a fill metal layer. Further metal layers may be included for other purposes, such as a barrier layer. The gate electrode of the gate 2122 may include any of the materials described above with reference to the gate electrode 214.

In some embodiments, when viewed as a cross-section of the transistor 2140 along the source-channel-drain direction, the gate electrode of the gate 2122 may include a U-shaped structure that includes a bottom portion substantially parallel to the surface of the substrate and two sidewall portions that are substantially perpendicular to the top surface of the substrate. In other embodiments, at least one of the metal layers that form the gate electrode may simply be a planar layer that is substantially parallel to the top surface of the substrate and does not include sidewall portions substantially perpendicular to the top surface of the substrate. In other embodiments, the gate electrode may include a combination of U-shaped structures and planar, non-U-shaped structures. For example, the gate electrode may include one or more U-shaped metal layers formed atop one or more planar, non-U-shaped layers. In some embodiments, the gate electrode may include a V-shaped structure (e.g., when the fin of a FinFET does not have a “flat” upper surface, but instead has a rounded peak).

In some embodiments, a pair of sidewall spacers may be formed on opposing sides of the gate stack to bracket the gate stack. The sidewall spacers may be formed from a material such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 2120 may be adjacent to the gate of each transistor 2140. The S/D regions 2120 may be formed using an implantation/diffusion process or an etching/deposition process, for example.

Various transistors 2140 are not limited to the type and configuration depicted in FIG. 9 and may include a wide variety of other types and configurations such as, for example, planar transistors, non-planar transistors (e.g., FinFETs, nanowire, or nanoribbon transistors), or a combination of transistors of different types and configurations.

The one or more interconnect layers 2106, 2108, 2110 may form an ILD stack 2119 of the IC structure 2100. In some embodiments, electrical signals, such as power and/or input/output (I/O) signals, may be routed to and/or from the transistors 2140 of the device layer 2104 and/or to memory implemented in the ILD stack 2119 of the IC structure 2100 through one or more interconnect layers disposed on the device layer 2104 (illustrated in FIG. 9 as interconnect layers 2106, 2108, 2110). For example, electrically conductive features of the device layer 2104 (e.g., the gate 2122 and the S/D contacts 2124) may be electrically coupled with the interconnect structures 2128 of the interconnect layers 2106, 2108, 2110.

The interconnect structures 2128 may be arranged within the interconnect layers 2106, 2108, 2110 to route electrical signals according to a wide variety of designs (in particular, the arrangement is not limited to the particular configuration of interconnect structures 2128 depicted in FIG. 9). Although a particular number of interconnect layers 2106, 2108, 2110 is depicted in FIG. 9, embodiments of the present disclosure include IC devices having more or fewer interconnect layers than depicted.

In some embodiments, the interconnect structures 2128 may include trench structures 2128a (sometimes referred to as “lines”) and/or via structures 2128B (sometimes referred to as “holes”) filled with an electrically conductive material such as a metal. The trench structures 2128a may be arranged to route electrical signals in a direction of a plane that is substantially parallel with the bottom of the device layer 2104. For example, the trench structures 2128a may route electrical signals in a direction in and out of the page from the perspective of FIG. 9. The via structures 2128b may be arranged to route electrical signals in a direction of a plane that is substantially perpendicular to the bottom of the device layer 2104. In some embodiments, the via structures 2128b may electrically couple trench structures 2128a of different interconnect layers 2106, 2108, 2110 together.

The interconnect layers 2106, 2108, 2110 may include a dielectric material 2126 disposed between the interconnect structures 2128, as shown in FIG. 9. In some embodiments, the dielectric material 2126 disposed between the interconnect structures 2128 in different ones of the interconnect layers 2106, 2108, 2110 may have different compositions; in other embodiments, the composition of the dielectric material 2126 between different interconnect layers 2106, 2108, 2110 may be the same. The dielectric material 2126 may include any of the insulator/dielectric materials described above.

A first interconnect layer 2106 (referred to as Metal 1 or “M1”) may be formed directly on the device layer 2104. In some embodiments, the first interconnect layer 2106 may include trench structures 2128a and/or via structures 2128B, as shown. The trench structures 2128a of the first interconnect layer 2106 may be coupled with contacts (e.g., the S/D contacts 2124) of the device layer 2104.

A second interconnect layer 2108 (referred to as Metal 2 or “M2”) may be formed directly on the first interconnect layer 2106. In some embodiments, the second interconnect layer 2108 may include via structures 2128B to couple the trench structures 2128a of the second interconnect layer 2108 with the trench structures 2128a of the first interconnect layer 2106. Although the trench structures 2128a and the via structures 2128B are structurally delineated with a line within each interconnect layer (e.g., within the second interconnect layer 2108) for the sake of clarity, the trench structures 2128a and the via structures 2128B may be structurally and/or materially contiguous (e.g., simultaneously filled during a dual-damascene process) in some embodiments.

A third interconnect layer 2110 (referred to as Metal 3 or “M3”) (and additional interconnect layers, as desired) may be formed in succession on the second interconnect layer 2108 according to similar techniques and configurations described in connection with the second interconnect layer 2108 or the first interconnect layer 2106.

The interconnect layers 2106, 2108, 2110 may be the metal layers M1-M3, described above. Further metal layers may be present in the IC structure 2100, as also described above.

In some embodiments, electrical signals, such as power and/or I/O signals, may be routed to and/or from the transistors 2140 of the device layer 2104 and/or to memory implemented in the ILD stack 2119 of the IC structure 2100 from the back-side power delivery structure 2102, as described above.

The IC structure 2100 may be formed on the wafer 2000 of FIG. 8A and may be included in a die, e.g., the die 2002 of FIG. 8B.

FIG. 10 is a side, cross-sectional view of an example IC package 2200 that may include one or more IC devices with stacks of IC structures with memory and back-side power delivery, according to some embodiments of the present disclosure. In some embodiments, the IC package 2200 may be a system-in-package (SiP).

The package substrate 2252 may be formed of a dielectric material (e.g., a ceramic, a buildup film, an epoxy film having filler particles therein, etc.), and may have conductive pathways extending through the dielectric material between the face 2272 and the face 2274, or between different locations on the face 2272, and/or between different locations on the face 2274. These conductive pathways may take the form of any of the interconnect structures 2128 discussed above with reference to FIG. 9.

The package substrate 2252 may include conductive contacts 2263 that are coupled to conductive pathways 2262 through the package substrate 2252, allowing circuitry within the dies or die arrangements 2256 and/or the interposer 2257 to electrically couple to various ones of the conductive contacts 2264 (or to other devices included in the package substrate 2252, not shown).

The IC package 2200 may include an interposer 2257 coupled to the package substrate 2252 via conductive contacts 2261 of the interposer 2257, first-level interconnects 2265, and the conductive contacts 2263 of the package substrate 2252. The first-level interconnects 2265 illustrated in FIG. 10 are solder bumps, but any suitable first-level interconnects 2265 may be used. In some embodiments, no interposer 2257 may be included in the IC package 2200; instead, the dies or die arrangements 2256 may be coupled directly to the conductive contacts 2263 at the face 2272 by first-level interconnects 2265.

The IC package 2200 may include one or more dies or die arrangements 2256, where at least one of the dies or die arrangements 2256 is an IC device with one or more stacks of IC structures with memory and back-side power delivery as described herein. The dies or die arrangements 2256 may be coupled to the interposer 2257 via conductive contacts 2254 of the dies or die arrangements 2256, first-level interconnects 2258, and conductive contacts 2260 of the interposer 2257. The conductive contacts 2260 may be coupled to conductive pathways (not shown) through the interposer 2257, allowing circuitry within the dies or die arrangements 2256 to electrically couple to various ones of the conductive contacts 2261 (or to other devices included in the interposer 2257, not shown). The first-level interconnects 2258 illustrated in FIG. 10 are solder bumps, but any suitable first-level interconnects 2258 may be used. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket). For any of the dies or die arrangements 2256 implemented as an IC device with one or more stacks of IC structures with memory and back-side power delivery as described herein, the conductive contacts 2254 may be coupled to the back-side interconnects 418 of the back-side power delivery structure 410 that are in the interconnect layer that is farthest away from the FEOL layer 420 on which the back-side power delivery structure 410 is provided (e.g., the conductive contacts 2254 may be coupled to the back-side interconnects 418 that are exposed at the back of the dies or die arrangements 2256). Thus, the power may be provided to the memory in the dies or die arrangements 2256, via the back-side interconnects 418, from the interposer 2257.

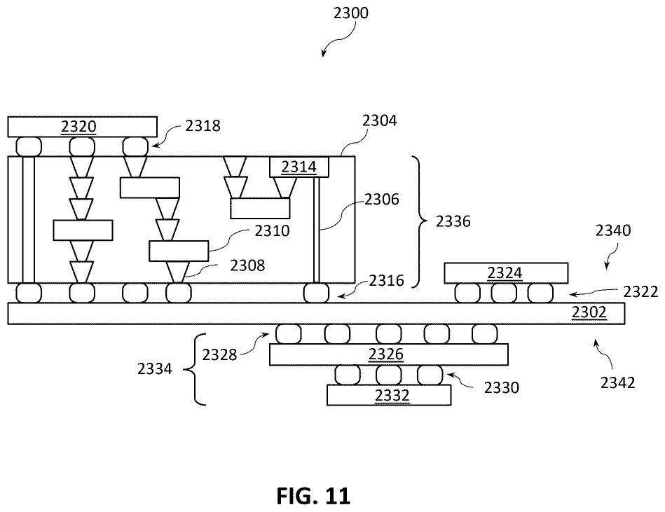

In some embodiments, an underfill material 2266 may be disposed between the package substrate 2252 and the interposer 2257 around the first-level interconnects 2265, and a mold compound 2268 may be disposed around the dies or die arrangements 2256 and the interposer 2257 and in contact with the package substrate 2252. In some embodiments, the underfill material 2266 may be the same as the mold compound 2268. Example materials that may be used for the underfill material 2266 and the mold compound 2268 are epoxy mold materials, as suitable. Second-level interconnects 2270 may be coupled to the conductive contacts 2264. The second-level interconnects 2270 illustrated in FIG. 10 are solder balls (e.g., for a ball grid array arrangement), but any suitable second-level interconnects 22770 may be used (e.g., pins in a pin grid array arrangement or lands in a land grid array arrangement). The second-level interconnects 2270 may be used to couple the IC package 2200 to another component, such as a circuit board (e.g., a motherboard), an interposer, or another IC package, as known in the art and as discussed below with reference to FIG. 11.

In some embodiments, the dies or die arrangements 2256 include any of the embodiments of the die 2002 discussed herein (e.g., may include any of the embodiments of the IC structure 2100). In embodiments in which the IC package 2200 includes multiple dies or die arrangements 2256, the IC package 2200 may be referred to as a multi-chip package (MCP). The dies or die arrangements 2256 may include circuitry to perform any desired functionality. For example, one or more of the dies or die arrangements 2256 may be logic dies (e.g., silicon-based dies), and one or more of the dies or die arrangements 2256 may be memory dies (e.g., high bandwidth memory), including embedded memory dies as described herein. In some embodiments, any of the dies or die arrangements 2256 may include IC devices with stacks of IC structures with memory and back-side power delivery, e.g., as discussed above; in some embodiments, at least some of the dies or die arrangements 2256 may not include any stacks of IC structures with memory and back-side power delivery.

The IC package 2200 illustrated in FIG. 10 may be a flip chip package, although other package architectures may be used. For example, the IC package 2200 may be a ball grid array (BGA) package, such as an embedded wafer-level ball grid array (eWLB) package. In another example, the IC package 2200 may be a wafer-level chip scale package (WLCSP) or a panel fan-out (FO) package. Although two dies or die arrangements 2256 are illustrated in the IC package 2200 of FIG. 10, an IC package 2200 may include any desired number of the dies or die arrangements 2256. An IC package 2200 may include additional passive components, such as surface-mount resistors, capacitors, and inductors disposed on the first face 2272 or the second face 2274 of the package substrate 2252, or on either face of the interposer 2257. More generally, an IC package 2200 may include any other active or passive components known in the art.

FIG. 11 is a cross-sectional side view of an IC device assembly 2300 that may include components having one or more IC devices with stacks of IC structures with memory and back-side power delivery, according to some embodiments of the present disclosure. The IC device assembly 2300 includes a number of components disposed on a circuit board 2302 (which may be, e.g., a motherboard). The IC device assembly 2300 includes components disposed on a first face 2340 of the circuit board 2302 and an opposing second face 2342 of the circuit board 2302; generally, components may be disposed on one or both faces 2340 and 2342. In particular, any suitable ones of the components of the IC device assembly 2300 may include any of one or more IC devices with stacks of IC structures with memory and back-side power delivery, according to some embodiments of the present disclosure; e.g., any of the IC packages discussed below with reference to the IC device assembly 2300 may take the form of any of the embodiments of the IC package 2200 discussed above with reference to FIG. 10 (e.g., may include one or more IC devices with stacks of IC structures with memory and back-side power delivery as part of one of the dies or die arrangements 2256).

In some embodiments, the circuit board 2302 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2302. In other embodiments, the circuit board 2302 may be a non-PCB substrate.

The IC device assembly 2300 illustrated in FIG. 11 includes a package-on-interposer structure 2336 coupled to the first face 2340 of the circuit board 2302 by coupling components 2316. The coupling components 2316 may electrically and mechanically couple the package-on-interposer structure 2336 to the circuit board 2302, and may include solder balls (e.g., as shown in FIG. 11), male and female portions of a socket, an adhesive, an underfill material, and/or any other suitable electrical and/or mechanical coupling structure.

The package-on-interposer structure 2336 may include an IC package 2320 coupled to an interposer 2304 by coupling components 2318. The coupling components 2318 may take any suitable form for the application, such as the forms discussed above with reference to the coupling components 2316. The IC package 2320 may be or include, for example, a die (the die 2002 of FIG. 8B), an IC device (e.g., the IC structure 2100 of FIG. 9), or any other suitable component. In particular, the IC package 2320 may include one or more IC devices with stacks of IC structures with memory and back-side power delivery as described herein. Although a single IC package 2320 is shown in FIG. 11, multiple IC packages may be coupled to the interposer 2304; indeed, additional interposers may be coupled to the interposer 2304. The interposer 2304 may provide an intervening substrate used to bridge the circuit board 2302 and the IC package 2320. Generally, the interposer 2304 may spread a connection to a wider pitch or reroute a connection to a different connection. For example, the interposer 2304 may couple the IC package 2320 (e.g., a die) to a BGA of the coupling components 2316 for coupling to the circuit board 2302. In the embodiment illustrated in FIG. 11, the IC package 2320 and the circuit board 2302 are attached to opposing sides of the interposer 2304; in other embodiments, the IC package 2320 and the circuit board 2302 may be attached to the same side of the interposer 2304. In some embodiments, three or more components may be interconnected by way of the interposer 2304.

The interposer 2304 may be formed of an epoxy resin, a fiberglass-reinforced epoxy resin, a ceramic material, or a polymer material such as polyimide. In some implementations, the interposer 2304 may be formed of alternate rigid or flexible materials that may include the same materials described above for use in a semiconductor substrate, such as silicon, germanium, and other group III-V and group IV materials. The interposer 2304 may include metal interconnects 2308 and vias 2310, including but not limited to through-silicon vias (TSVs) 2306. The interposer 2304 may further include embedded devices 2314, including both passive and active devices. Such devices may include, but are not limited to, capacitors, decoupling capacitors, resistors, inductors, fuses, diodes, transformers, sensors, electrostatic discharge (ESD) protection devices, and memory devices. More complex devices such as radio frequency (RF) devices, power amplifiers, power management devices, antennas, arrays, sensors, and microelectromechanical systems (MEMS) devices may also be formed on the interposer 2304. The package-on-interposer structure 2336 may take the form of any of the package-on-interposer structures known in the art.

The IC device assembly 2300 may include an IC package 2324 coupled to the first face 2340 of the circuit board 2302 by coupling components 2322. The coupling components 2322 may take the form of any of the embodiments discussed above with reference to the coupling components 2316, and the IC package 2324 may take the form of any of the embodiments discussed above with reference to the IC package 2320.

The IC device assembly 2300 illustrated in FIG. 11 includes a package-on-package structure 2334 coupled to the second face 2342 of the circuit board 2302 by coupling components 2328. The package-on-package structure 2334 may include an IC package 2326 and an IC package 2332 coupled together by coupling components 2330 such that the IC package 2326 is disposed between the circuit board 2302 and the IC package 2332. The coupling components 2328 and 2330 may take the form of any of the embodiments of the coupling components 2316 discussed above, and the IC packages 2326 and 2332 may take the form of any of the embodiments of the IC package 2320 discussed above. The package-on-package structure 2334 may be configured in accordance with any of the package-on-package structures known in the art.

FIG. 12 is a block diagram of an example computing device 2400 that may include one or more components with one or more IC devices with stacks of IC structures with memory and back-side power delivery, according to some embodiments of the present disclosure. For example, any suitable ones of the components of the computing device 2400 may include a die (e.g., the die 2002 (FIG. 8B)) that may later be includes in one of the IC devices with stacks of IC structures with memory and back-side power delivery, according to some embodiments of the present disclosure. Any of the components of the computing device 2400 may include an IC structure 2100 (FIG. 9) and/or an IC package 2200 (FIG. 10). Any of the components of the computing device 2400 may include an IC device assembly 2300 (FIG. 11).

A number of components are illustrated in FIG. 12 as included in the computing device 2400, but any one or more of these components may be omitted or duplicated, as suitable for the application. In some embodiments, some or all of the components included in the computing device 2400 may be attached to one or more motherboards. In some embodiments, some or all of these components are fabricated onto a single SoC die.

Additionally, in various embodiments, the computing device 2400 may not include one or more of the components illustrated in FIG. 12, but the computing device 2400 may include interface circuitry for coupling to the one or more components. For example, the computing device 2400 may not include a display device 2406, but may include display device interface circuitry (e.g., a connector and driver circuitry) to which a display device 2406 may be coupled. In another set of examples, the computing device 2400 may not include an audio input device 2418 or an audio output device 2408 but may include audio input or output device interface circuitry (e.g., connectors and supporting circuitry) to which an audio input device 2418 or audio output device 2408 may be coupled.

The computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2402 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices. The computing device 2400 may include a memory 2404, which may itself include one or more memory devices such as volatile memory (e.g., DRAM), nonvolatile memory (e.g., read-only memory (ROM)), flash memory, solid state memory, and/or a hard drive. In some embodiments, the memory 2404 may include memory that shares a die with the processing device 2402. This memory may be used as cache memory. The memory 2404 may include memory that is part of one or more IC devices with stacks of IC structures with memory and back-side power delivery as described herein.

In some embodiments, the computing device 2400 may include a communication chip 2412 (e.g., one or more communication chips). For example, the communication chip 2412 may be configured for managing wireless communications for the transfer of data to and from the computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2412 may implement any of a number of wireless standards or protocols, including but not limited to Institute for Electrical and Electronic Engineers (IEEE) standards including Wi-Fi (IEEE 602.11 family), IEEE 602.16 standards (e.g., IEEE 602.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 602.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 602.16 standards. The communication chip 2412 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 2412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2412 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2412 may operate in accordance with other wireless protocols in other embodiments. The computing device 2400 may include an antenna 2422 to facilitate wireless communications and/or to receive other wireless communications (such as AM or FM radio transmissions).

In some embodiments, the communication chip 2412 may manage wired communications, such as electrical, optical, or any other suitable communication protocols (e.g., the Ethernet). As noted above, the communication chip 2412 may include multiple communication chips. For instance, a first communication chip 2412 may be dedicated to shorter-range wireless communications such as Wi-Fi or Bluetooth, and a second communication chip 2412 may be dedicated to longer-range wireless communications such as global positioning system (GPS), EDGE, GPRS, CDMA, WiMAX, LTE, EV-DO, or others. In some embodiments, a first communication chip 2412 may be dedicated to wireless communications, and a second communication chip 2412 may be dedicated to wired communications.

The computing device 2400 may include battery/power circuitry 2414. The battery/power circuitry 2414 may include one or more energy storage devices (e.g., batteries or capacitors) and/or circuitry for coupling components of the computing device 2400 to an energy source separate from the computing device 2400 (e.g., AC line power).

The computing device 2400 may include a display device 2406 (or corresponding interface circuitry, as discussed above). The display device 2406 may include any visual indicators, such as a heads-up display, a computer monitor, a projector, a touchscreen display, a liquid crystal display (LCD), a light-emitting diode display, or a flat panel display, for example.

The computing device 2400 may include an audio output device 2408 (or corresponding interface circuitry, as discussed above). The audio output device 2408 may include any device that generates an audible indicator, such as speakers, headsets, or earbuds, for example.

The computing device 2400 may include an audio input device 2418 (or corresponding interface circuitry, as discussed above). The audio input device 2418 may include any device that generates a signal representative of a sound, such as microphones, microphone arrays, or digital instruments (e.g., instruments having a musical instrument digital interface (MIDI) output).

The computing device 2400 may include a GPS device 2416 (or corresponding interface circuitry, as discussed above). The GPS device 2416 may be in communication with a satellite-based system and may receive a location of the computing device 2400, as known in the art.

The computing device 2400 may include an other output device 2410 (or corresponding interface circuitry, as discussed above). Examples of the other output device 2410 may include an audio codec, a video codec, a printer, a wired or wireless transmitter for providing information to other devices, or an additional storage device.

The computing device 2400 may include an other input device 2420 (or corresponding interface circuitry, as discussed above). Examples of the other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 2400 may be any other electronic device that processes data.

The following paragraphs provide various examples of the embodiments disclosed herein.
Example 1 provides an IC device that includes a first die including a first layer of memory cells, a first power delivery structure, and a layer of signal interconnects, where the first layer of memory cells is between the first power delivery structure and the layer of signal interconnects; a second die including a second layer of memory cells and a second power delivery structure; and a bonding interface between the first die and the second die, where the bonding interface is between (e.g., in contact with) the layer of signal interconnects of the first die and the second layer of memory cells of the second die.
Example 2 provides the IC device according to example 1, where the second layer of memory cells is between (e.g., in contact with) the bonding interface and the second power delivery structure.
Example 3 provides the IC device according to examples 1 or 2, where the layer of signal interconnects is between (e.g., in contact with) the first layer of memory cells and the bonding interface.
Example 4 provides the IC device according to any one of the preceding examples, where the bonding interface includes silicon and one or more of nitrogen and carbon.
Example 5 provides the IC device according to any one of the preceding examples, where: each of the first die and the second die includes a first face and an opposing second face, the bonding interface is between (e.g., in contact with) the second face of the first die and the first face of the second die, and the IC device further includes a conductive via (e.g., an after-bonding via) extending from the second face of the second die to one or more interconnects of the layer of signal interconnects.
Example 6 provides the IC device according to example 5, where the conductive via extends through the second die, through the bonding interface, and into the first die.
Example 7 provides the IC device according to examples 5 or 6, where: in a plane that is substantially perpendicular to the bonding interface, each of a cross-section of the conductive via, a cross-section of at least one interconnect of the first power delivery structure, and a cross-section of at least one interconnect of the second power delivery structure has two sides that are substantially parallel, where a first side is longer than a second side, for the each of the cross-section of the conductive via, the cross-section of the at least one interconnect of the first power delivery structure, and the cross-section of the at least one interconnect of the second power delivery structure, the second side is closer to the bonding interface than the first side.
Example 8 provides the IC device according to examples 5 or 6, where: in a plane that is substantially perpendicular to the bonding interface, each of a cross-section of the conductive via and a cross-section of at least one interconnect of the layer of signal interconnects has two sides that are substantially parallel, where a first side is longer than a second side, for the cross-section of the conductive via, the second side is closer to the bonding interface than the first side, and for the cross-section of the at least one interconnect of the layer of signal interconnects, the first side is closer to the bonding interface than the second side.
Example 9 provides the IC device according to any one of examples 1-4, where: each of the first die and the second die includes a first face and an opposing second face, the bonding interface is between (e.g., in contact with) the second face of the first die and the first face of the second die, and the IC device further includes a conductive via (e.g., an after-bonding via) extending from the first face of the first die to one or more interconnects of the layer of signal interconnects.
Example 10 provides the IC device according to example 9, where: in a plane that is substantially perpendicular to the bonding interface, each of a cross-section of the conductive via, a cross-section of at least one interconnect of the first power delivery structure, and a cross-section of at least one interconnect of the second power delivery structure has two sides that are substantially parallel, where a first side is longer than a second side, for the each of the cross-section of the conductive via, the cross-section of the at least one interconnect of the first power delivery structure, and the cross-section of the at least one interconnect of the second power delivery structure, the second side is closer to the bonding interface than the first side.
Example 11 provides the IC device according to example 9, where: in a plane that is substantially perpendicular to the bonding interface, each of a cross-section of the conductive via and a cross-section of at least one interconnect of the layer of signal interconnects has two sides that are substantially parallel, where a first side is longer than a second side, for the cross-section of the conductive via, the second side is closer to the bonding interface than the first side, and for the cross-section of the at least one interconnect of the layer of signal interconnects, the first side is closer to the bonding interface than the second side.
Example 12 provides the IC device according to any one of the preceding examples, where the bonding interface is a first bonding interface, and where the IC device further includes a third die including a third layer of memory cells and a third power delivery structure; and a second bonding interface between (e.g., in contact with) the second die and the third die, where the second bonding interface is between (e.g., in contact with) the second power delivery structure of the second die and the third power delivery structure of the third die.
Example 13 provides the IC device according to example 12, further including: a fourth die including a fourth layer of memory cells and a fourth power delivery structure; and a third bonding interface between (e.g., in contact with) the third die and the fourth die.
Example 14 provides the IC device according to example 13, where: the layer of signal interconnects is a first layer of signal interconnects, the third die further includes a second layer of signal interconnects, and the third bonding interface is between (e.g., in contact with) the second layer of signal interconnects of the third die and the fourth layer of memory cells of the fourth die.
Example 15 provides the IC device according to example 13, where: the layer of signal interconnects is a first layer of signal interconnects, the fourth die further includes a second layer of signal interconnects, and the third bonding interface is between (e.g., in contact with) the third layer of memory cells of the third die and the second layer of signal interconnects of the fourth die.
Example 16 provides an integrated circuit (IC) device, including a first IC structure including a layer of memory cells, a power delivery structure at a back side of the layer of memory cells, and a layer of signal interconnects at a front side of the layer of memory cells; and a second IC structure attached to the layer of signal interconnects of the first IC structure, the second IC structure including a layer of memory cells and a power delivery structure at a back side of the layer of memory cells of the second IC structure.
Example 17 provides the IC device according to example 16, where the layer of signal interconnects of the first IC structure is to provide signals to memory cells of the layer of memory cells of the first IC structure and of the layer of memory cells of the second IC structure.
Example 18 provides the IC device according to examples 16 or 17, where the layer of signal interconnects of the first IC structure is between (e.g., in contact with) the layer of memory cells of the first IC structure and the layer of memory cells of the second IC structure.
Example 19 provides an integrated circuit (IC) device, including a first IC structure including a first layer of memory cells, a first interconnect network at a back side of the first layer of memory cells, and a second interconnect network at a front side of the first layer of memory cells; a second IC structure including a second layer of memory cells and a third interconnect network at a back side of the second layer of memory cells; and a bonding interface between (e.g., in contact with) the second interconnect network and the second layer of memory cells, where average dimensions of interconnects of the second interconnect network are smaller than average dimensions of interconnects of the first interconnect network and smaller than average dimensions of interconnects of the third interconnect network.
Example 20 provides the IC device according to example 19, where one or more memory cells of the second layer of memory cells are electrically connected to one or more of the interconnects of the second interconnect network through the bonding interface.
Example 21 provides an integrated circuit (IC) package, including an IC device; and a further component, coupled to the IC device, where the IC device includes an IC device according to any one of the preceding examples.
Example 22 provides the IC package according to example 21, where the further component is one of a package substrate, an interposer, or an IC die.
Example 23 provides the IC package according to any one of examples 21-22, further including an insulator material around at least a portion of the IC device.
Example 24 provides the IC package according to any one of examples 21-23, further including interconnects between the further component and the IC device.
Example 25 provides the IC package according to example 24, where the interconnects are solder bumps.
Example 26 provides the IC package according to example 24, where the interconnects are hybrid bonding interconnects.
Example 27 provides the IC package according to any one of examples 24-26, further including first conductive contacts at a surface of the further component closest to the IC device; and second conductive contacts at a surface of the IC device closest to the further component, where the interconnects are between the first conductive contacts and the second conductive contacts.
Example 28 provides the IC package according to example 27, where at least one of the first conductive contacts or the second conductive contacts includes a conductive pad.
Example 29 provides the IC package according to example 27, where at least one of the first conductive contacts or the second conductive contacts includes a conductive socket.
Example 30 provides the IC package according to any one of examples 21-29, where: the further component is an interposer, the IC package further includes a package substrate coupled to the interposer, the IC device is coupled to a first face of the interposer, and the package substrate is coupled to a second face of the interposer opposite the first face of the interposer.
Example 31 provides the IC package according to example 30, further including interconnects between the interposer and the package substrate.
Example 32 provides the IC package according to example 31, further including an underfill material around the interconnects.
Example 33 provides an electronic device, including a carrier substrate; and one or more of the IC devices according to any one of the preceding examples and/or the IC package according to any one of the preceding claims, coupled to the carrier substrate.
Example 34 provides the electronic device according to example 33, where the carrier substrate is a motherboard.
Example 35 provides the electronic device according to example 33, where the carrier substrate is a PCB.
Example 36 provides the electronic device according to any one of examples 33-35, where the electronic device is a wearable electronic device (e.g., a smart watch) or handheld electronic device (e.g., a mobile phone).
Example 37 provides the electronic device according to any one of examples 33-36, where the electronic device further includes one or more communication chips and an antenna.
Example 38 provides the electronic device according to any one of examples 33-37, where the electronic device is memory device.
Example 39 provides the electronic device according to any one of examples 33-37, where the electronic device is a computing device.
The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) device, comprising:
a first die comprising a first layer of memory cells, a first power delivery structure, and a layer of signal interconnects, wherein the first layer of memory cells is between the first power delivery structure and the layer of signal interconnects;
a second die comprising a second layer of memory cells and a second power delivery structure; and
a bonding interface between the first die and the second die, wherein the bonding interface is between the layer of signal interconnects and the second layer of memory cells.

2. The IC device according to claim 1, wherein the second layer of memory cells is between the bonding interface and the second power delivery structure.

3. The IC device according to claim 1, wherein the layer of signal interconnects is between the first layer of memory cells and the bonding interface.

4. The IC device according to claim 1, wherein the bonding interface includes silicon and one or more of nitrogen and carbon.

5. The IC device according to claim 1, wherein:
each of the first die and the second die includes a first face and an opposing second face,
the bonding interface is between the second face of the first die and the first face of the second die, and
the IC device further includes a conductive via extending from the second face of the second die to one or more interconnects of the layer of signal interconnects.

6. The IC device according to claim 5, wherein the conductive via extends through the second die, through the bonding interface, and into the first die.

7. The IC device according to claim 5, wherein:
in a plane that is substantially perpendicular to the bonding interface, each of a cross-section of the conductive via, a cross-section of at least one interconnect of the first power delivery structure, and a cross-section of at least one interconnect of the second power delivery structure has two sides that are substantially parallel, wherein a first side is longer than a second side, and
for the each of the cross-section of the conductive via, the cross-section of the at least one interconnect of the first power delivery structure, and the cross-section of the at least one interconnect of the second power delivery structure, the second side is closer to the bonding interface than the first side.

8. The IC device according to claim 5, wherein:
in a plane that is substantially perpendicular to the bonding interface, each of a cross-section of the conductive via and a cross-section of at least one interconnect of the layer of signal interconnects has two sides that are substantially parallel, wherein a first side is longer than a second side,
for the cross-section of the conductive via, the second side is closer to the bonding interface than the first side, and
for the cross-section of the at least one interconnect of the layer of signal interconnects, the first side is closer to the bonding interface than the second side.

9. The IC device according to claim 1, wherein:
each of the first die and the second die includes a first face and an opposing second face,
the bonding interface is between the second face of the first die and the first face of the second die, and
the IC device further includes a conductive via extending from the first face of the first die to one or more interconnects of the layer of signal interconnects.

10. The IC device according to claim 9, wherein:
in a plane that is substantially perpendicular to the bonding interface, each of a cross-section of the conductive via, a cross-section of at least one interconnect of the first power delivery structure, and a cross-section of at least one interconnect of the second power delivery structure has two sides that are substantially parallel, wherein a first side is longer than a second side, and
for the each of the cross-section of the conductive via, the cross-section of the at least one interconnect of the first power delivery structure, and the cross-section of the at least one interconnect of the second power delivery structure, the second side is closer to the bonding interface than the first side.

11. The IC device according to claim 9, wherein:
in a plane that is substantially perpendicular to the bonding interface, each of a cross-section of the conductive via and a cross-section of at least one interconnect of the layer of signal interconnects has two sides that are substantially parallel, wherein a first side is longer than a second side,
for the cross-section of the conductive via, the second side is closer to the bonding interface than the first side, and
for the cross-section of the at least one interconnect of the layer of signal interconnects, the first side is closer to the bonding interface than the second side.

12. The IC device according to claim 1, wherein the bonding interface is a first bonding interface, and wherein the IC device further includes:
a third die comprising a third layer of memory cells and a third power delivery structure; and
a second bonding interface between the second die and the third die, wherein the second bonding interface is between the second power delivery structure and the third power delivery structure.

13. The IC device according to claim 12, further including:
a fourth die comprising a fourth layer of memory cells and a fourth power delivery structure; and
a third bonding interface between the third die and the fourth die.

14. The IC device according to claim 13, wherein:
the layer of signal interconnects is a first layer of signal interconnects,
the third die further includes a second layer of signal interconnects, and
the third bonding interface is between the second layer of signal interconnects and the fourth layer of memory cells.

15. The IC device according to claim 13, wherein:
the layer of signal interconnects is a first layer of signal interconnects,
the fourth die further includes a second layer of signal interconnects, and
the third bonding interface is between the third layer of memory cells and the second layer of signal interconnects.

16. An integrated circuit (IC) device, comprising:
a first IC structure comprising a layer of memory cells, a power delivery structure at a back side of the layer of memory cells, and a layer of signal interconnects at a front side of the layer of memory cells; and
a second IC structure attached to the layer of signal interconnects of the first IC structure, the second IC structure comprising a layer of memory cells and a power delivery structure at a back side of the layer of memory cells of the second IC structure.

17. The IC device according to claim 16, wherein the layer of signal interconnects of the first IC structure is to provide signals to memory cells of the layer of memory cells of the first IC structure and of the layer of memory cells of the second IC structure.

18. The IC device according to claim 16, wherein the layer of signal interconnects of the first IC structure is between the layer of memory cells of the first IC structure and the layer of memory cells of the second IC structure.

19. An integrated circuit (IC) device, comprising:
a first IC structure comprising a first layer of memory cells, a first interconnect network at a back side of the first layer of memory cells, and a second interconnect network at a front side of the first layer of memory cells;
a second IC structure comprising a second layer of memory cells and a third interconnect network at a back side of the second layer of memory cells; and
a bonding interface between the second interconnect network and the second layer of memory cells,
wherein average dimensions of interconnects of the second interconnect network are smaller than average dimensions of interconnects of the first interconnect network and smaller than average dimensions of interconnects of the third interconnect network.

20. The IC device according to claim 19, wherein one or more memory cells of the second layer of memory cells are electrically connected to one or more of the interconnects of the second interconnect network through the bonding interface.
